(19) United States
(12) Patent Application Publication
(10) Pub. No.: US 2006/0221576 A1
(43) Pub. Date: Oct. 5, 2006

(54) Radiator device and plug-in unit

(75) Inventors: Wataru Takano, Yokohama (JP); Katsuhiko Ikeda, Yokohama (JP); Kazuo Fujita, Yokohama (JP); Minoru Fujii, Yokohama (JP); Hideki Zenitani, Yokohama (JP)

Correspondence Address: KATTEN MUCHIN ROSENMAN LLP, 575 MADISON AVENUE, NEW YORK, NY, 10022-2585, US

(73) Assignee: FUJITSU LIMITED

(21) Appl. No.: 11/189,658

(22) Filed: Jul. 26, 2005

(30) Foreign Application Priority Data
Mar. 30, 2005 (JP) 2005-099057

(51) Int. Cl. H05K 7/20

(52) U.S. Cl. 361/719

(57) ABSTRACT

The radiator device which radiates heat generated by electronic components mounted on a printed board, and the plug-in unit which the radiator device is equipped to is provided in order to reliably absorb errors in height among various electronic components while realizing a high heat radiation efficiency. The device and the plug-in unit includes: a radiating board which is connected to an electronic component side of a printed board mounted with one or more electronic components thereon, with a specific space between the radiating board and the printed board; a heat conductive block which is connected to a side of the radiating board that faces the printed board in such a manner that the position of the heat conductive block is adjustable along a direction crossing the printed board, the heat conductive block making intimate contact with an electronic component mounted on the printed board.

### BACKGROUND OF THE INVENTION

1. Field of the Invention

The present invention relates to an art of radiating heat generated by electronic components mounted on a printed board. The invention relates particularly to an art suitable for use in a plug-in unit which is inserted in a sub-rack apparatus.

2. Description of the Related Art

There is an art of radiating heat generated by electronic components (for example, LSI; Large Scale Integration) mounted on a printed board by means of radiating fins, and this art is applied to a communication apparatus as shown in FIG. 43 and FIG. 44.

The communication apparatus 1 of FIG. 43 and FIG. 44 includes plug-in units 2 each having a printed board 2a on which electronic components are mounted and a sub-rack 3 into which the plug-in units 2 are inserted. The sub-rack 3 is stored in the sub-rack mounting rack 4, and has cooling fans 3a which have air flow in a direction indicated by arrow 3b for cooling the plug-in units 2.

In the communication apparatus 1, as shown in FIG. 44, plug-in units 2 are inserted into the sub-rack 3 in the c1-c2 direction, and connectors 2b of the plug-in units 2 are connected to back plane connectors (not shown) inside the sub-rack 3, whereby an electric connection is established between the plug-in units 2 and the sub-rack 3.

FIG. 45 is a top view of a plug-in unit 2. As shown in FIG. 45, more than one electronic component 2c is mounted on a printed board 2a of a plug-in unit 2. Radiating fins 5 are provided, as shown by broken lines, on electronic components (hereinafter will be called “LSI”) 2c that generate heat.

Here, referring to FIG. 46(a), FIG. 46(b), FIG. 47(a), and FIG. 47(b), a description will made of installation of a conventional radiating fin 5 on an LSI 2c. In the example shown in FIG. 46(a) and FIG. 46(b), a radiating fin 5 is directly fixed on the LSI 2c, which is mounted on the printed board 2a via leads 2d, with an adhesive agent.

In this manner, radiating fins 5 directly fixed on LSIs 2c with an adhesive agent are advantaged in that radiation efficiency is high, but on the other hand it is disadvantaged in that model numbers and manufacturers' names printed or attached on the upper surface of the LSIs 2c cannot be read. Thus, if a necessity arises of checking the model number or the manufacturer's name of an electronic component 2c, which information is described on the upper surface of the electronic component 2c, for the purpose of modification or repair to be added to the printed board 2a, the radiating fins 5 fixed on the LSI 2c with an adhesive agent must be removed, which is a difficult operation.

Therefore, in the example of FIG. 47(a) and FIG. 47(b), a radiating fin 5 is mounted on an LSI 2c, which is mounted on the printed board 2a via leads 2d, via a radiating fin mounting hardware 5a. In this example, the radiating fin mounting hardware 5a is fastened to the printed board 2a so as to cover the LSI 2c, with the radiating fin mounting hardware 5a making intimate contact with the upper surface of the LSI 2c.

In this manner, in cases where radiating fins 5 are mounted on the LSIs 2c via the radiating fin mounting hardware 5a, it is possible to easily detach the radiating fins 5 so that letters printed on the LSIs 2c can be easily read unless the letters are hidden by the radiating fin mounting hardware 5a.

However, in the example of FIG. 47(a) and FIG. 47(b), holes and a space for installing the radiating fin mounting hardware 5a on the printed board 2a is necessary, and also, a space for attaching/detaching the radiating fin 5 on the radiating fin mounting hardware 5a is necessary, so that dense mounting of electronic components 2c becomes difficult.

With recent progress in down-sizing of electronic components and dense integration, dense mounting of electronic components 2c on the printed board 2a is progressed in the plug-in units 2 of the communication apparatus 1. Under such circumstances, power consumption of the printed board 2a tends to be increased, and the amount of heat radiated from the printed board 2a is also increased.

Further, with increase in operation speed of LSIs 2c mounted on the printed board 2a, power consumption is more and more increased, and the amount of heat radiated from LSIs 2c themselves is increased.

As a result, in the above art described referring to FIG. 46(a), FIG. 46(b), FIG. 47(a), and FIG. 47(b), in which only radiating fins 5 are provided for LSIs 2c, heat generated by the LSIs 2c of the printed board 2a cannot be sufficiently radiated, so that it is impossible to sufficiently cool down the LSIs 2c and the printed board 2a.

Further, the height of the radiating fins 5 is limited when the sheet pitches of the plug-in units 2 are small, and when the plug-in units 2 are covered by shield covers. Thus, the art in which radiating fins 5 are provided, one for each LSI 2c, has difficulty in satisfying the permissible junction temperature value.

Here, when the height of the radiating fins 5 is limited, it is possible that the diameter of the radiating fins 5 is increased for improving the heat radiation efficiency. However, if the diameters of the radiating fins 5 are increased, mounting of other electronic components 2c in the vicinity of the LSIs 2c needs to be limited, so that high-density mounting becomes unavailable.

Therefore, there have been arts for radiating heat generated by electronic components (LSIs) by using radiating boards as well as radiating fins. In an example, each component (electronic component) mounted on a printed board is provided with a heat conductive piece (heat radiating fin), and on the heat conductive piece is provided a heat conductive board (heat radiating board) (for example, see the following patent document 1). In another example, bellows are provided for electronic components mounted on a printed board via heat conductive mats, and such bellows are mounted with lids (radiating board) (for example, see the following patent document 2).

However, in the art of the following patent document 1, if the heights of the electronic components mounted on the printed board are not uniform, the distance between the upper surfaces of the electronic components and the radiating board differs among the electronic components. Thus, the height of each of the radiating fins must be adjusted corresponding to the height of each of the electronic components, so that manufacturing process of the radiating fins becomes complicated and the manufacturing cost is increased.

Accordingly, in patent document 1, flat springs are formed on the radiating board at positions corresponding to electronic components. With this arrangement, if the heights of the radiating fins are equal, errors in height of the electronic components are absorbed.

However, such formation of flat springs, which are made by processing the radiating board, makes the connection parts between the whole radiating board and the radiating fins small, so that the heat conductive efficiency from the radiating fins to the radiating board is deteriorated, whereby the heat radiation efficiency is decreased.

Further, patent document 1 also discloses that heat conductive rubber, instead of heat radiating fins, is used for the purpose of absorbing errors in height among various electronic components. This technique absorbs the errors in height among the electronic components only by means of the compressibility of the heat conductive rubber. Thus, this technique is applicable only to cases where errors in height of the electronic components are small, and cannot be applied to cases where the errors in height are large.

In addition, since the art in patent document 2 utilizes hollow bellows, instead of radiating fins, the heat conductive efficiency to a radiating board is low, and thus the heat radiation efficiency is low.

[Patent Document 1] Japanese Patent Application Publication No. HEI 5-315777

[Patent Document 2] Japanese Patent Application Publication No. HEI 5-53293

### SUMMARY OF THE INVENTION

With the foregoing problems in view, it is an object of the present invention to provide a heat radiator device which exhibits a high heat radiation efficiency while absorbing errors in height among various electronic components mounted on a printed board.

In order to accomplish the above object, according to the present invention, there is provided a radiator device, comprising: a radiating board which is connected to an electronic component side of a printed board mounted with one or more electronic components thereon, with a specific space between the radiating board and the printed board; and a heat conductive block which is connected to a side of the radiating board that faces the printed board in such a manner that the position of the heat conductive block is adjustable along a direction crossing the printed board, the heat conductive block making intimate contact with an electronic component mounted on the printed board.

As one preferred feature, the heat conductive block is grooved on its peripheral surface, and the heat conductive block is screwed in a tapped hole provided on the radiating board.

As another preferred feature, the heat conductive block includes: a heat conductive member which makes intimate contact with the electronic component mounted on the printed board; and a cushion member interposed between the heat conductive member and the radiating board, the cushion member being heat conductive. In this instance, the heat conductive member and the radiating board are combined by means of a screw mechanism, and the cushion member is sandwiched between the heat conductive member and the radiating board.

As yet another preferred feature, the heat conductive member has a wall part thereof so that the heat conductive member has a concave part thereof relative to the radiating board, and the cushion member is placed in the concave part which is formed by the wall part of the heat conductive member, and the radiating board has a mating part which mates with the concave part formed by the wall part of the heat conductive member. In this instance, a heat-conductive intimate contact member is provided between an inner peripheral surface of the wall part of the heat conductive member and an outer peripheral surface of the mating part of the radiating board so as to fill a gap therebetween.

As a further preferred feature, the wall part of the heat conductive member is provided on an outside edge of the heat conductive member.

As a yet further preferred feature, the heat conductive block has one or more projections extending toward the radiating board, and one or more through holes are formed, for letting the projections pass therethrough, on the radiating board at positions corresponding to the one or more projections of the conductive block.

As a furthermore preferred feature, the radiating board has two or more connection parts which connect the radiating board with the printed board, and the radiating board has a cut formed thereon so that the radiating board has a spring force which presses the heat conductive block against the printed board with the two or more connection parts as fulcrums.

As another generic feature, there is provided a plug-in unit, comprising: a printed board on which one or more electronic components are mounted; a radiating board which is connected to an electronic component side of the printed board, with a specific space between the radiating board and the printed board; and a heat conductive block which is connected to a side of the radiating board that faces the printed board in such a manner that the position of the heat conductive block is adjustable along a direction crossing the printed board, the heat conductive block making intimate contact with an electronic component mounted on the printed board.

According to the present invention, since heat generated by electronic components mounted on a printed board is transferred to a radiating board having a large area via heat conductive blocks which make intimate contact with the electronic components, a high heat radiation efficiency is realized.

Further, even if the heights of the electronic components mounted on the printed board are not equal, the heat conductive block is connected in such a manner that the position of the heat conductive block is adjustable along a direction crossing the printed board, so that errors in height among various electronic components are reliably absorbed by adjusting the position of the heat conductive block.

Other objects and further features of the present invention will be apparent from the following detailed description when read in conjunction with the accompanying drawings.

### BRIEF DESCRIPTION OF THE DRAWINGS

FIG. 1 is an exploded perspective view of a communication apparatus for which a radiator device according to a first embodiment of the present invention is provided;

FIG. 2 is an exploded perspective view of a plug-in unit for which a radiator device according to the first embodiment is provided;

FIG. 3(a) and FIG. 3(b) are a top view and a side view, respectively, of a heat conductive member of the radiator device of the first embodiment;

FIG. 4(a) and FIG. 4(b) are a top view and a side view, respectively, of a heat conductive sheet of the radiator device of the first embodiment;

FIG. 5(a) and FIG. 5(b) are a top view and a side view, respectively, of a radiating board of the radiator device of the first embodiment;

FIG. 6 is an exploded perspective view for describing an assembly sequence of the radiator device of the first embodiment;

FIG. 7 is an exploded perspective view for describing the assembly sequence of the radiator device of the first embodiment;

FIG. 8 is a perspective view for describing the assembly sequence of the radiator device of the first embodiment;

FIG. 9(a) and FIG. 9(b) are views for describing position adjustment of a heat conductive block of the radiator device of the first embodiment: FIG. 9(a) is an exploded side view of the heat conductive block before position adjustment is performed; FIG. 9(b) is a side view of the heat conductive block after position adjustment is completed;

FIG. 10(a) through FIG. 10(c) are a top view, an A-A (of FIG. 10(a)) sectional view, and a side view, respectively, of the radiator device of the first embodiment;

FIG. 11 is an enlarged view of the sectional view of FIG. 10(b);

FIG. 12 is a sectional view illustrating an example in which the radiator device of the first embodiment is connected with a printed board on which more than one electronic component is mounted;

FIG. 13(a) through FIG. 13(c) are a top view, a B-B (of FIG. 13(a)) sectional view, and a side view, respectively, of a radiator device according to a second embodiment of the present invention;

FIG. 14(a) and FIG. 14(b) are a top view and a side view, respectively, of a heat conductive member of the radiator device of the second embodiment;

FIG. 15 (a) and FIG. 15(b) are a top view and a side view, respectively, of a heat conductive sheet of the radiator device of the second embodiment;

FIG. 16(a) and FIG. 16(b) are a top view and a side view, respectively, of a radiating board of the radiator device of the second embodiment;

FIG. 17 is an exploded perspective view for describing an assembly sequence of the radiator device of the second embodiment;

FIG. 18 is an exploded perspective view for describing the assembly sequence of the radiator device of the second embodiment;

FIG. 19 is a perspective view for describing the assembly sequence of the radiator device of the second embodiment;

FIG. 20 is a C-C cross sectional view of the perspective view of FIG. 19;

FIG. 21(a) and FIG. 21(b) are views for describing position adjustment of a heat conductive block of the radiator device of the second embodiment: FIG. 21(a) is an exploded side view of the heat conductive block before position adjustment is performed; FIG. 21(b) is a side view of the heat conductive block after position adjustment is completed;

FIG. 22 is a cross sectional view illustrating an example in which the radiator device of the second embodiment is connected with a printed board on which an electronic component is mounted;

FIG. 23(a) through FIG. 23(c) are a top view, a D-D (of FIG. 23(a)) sectional view, and a side view, respectively, of a radiator device according to a third embodiment of the present invention;

FIG. 24(a) and FIG. 24(b) are a top view and a side view, respectively, of a heat conductive member of the radiator device of the third embodiment;

FIG. 25(a) and FIG. 25(b) are a top view and a side view, respectively, of a heat conductive sheet of the radiator device of the third embodiment;

FIG. 26(a) and FIG. 26(b) are a top view and a side view, respectively, of a mating part of the radiator device of the third embodiment;

FIG. 27(a) and FIG. 27(b) are a top view and a side view, respectively, of the radiating board of the radiator device of the third embodiment;

FIG. 28 is an exploded perspective view for describing an assembly sequence of the radiator device of the third embodiment;

FIG. 29 is an exploded perspective view for describing the assembly sequence of the radiator device of the third embodiment;

FIG. 30 is a perspective view for describing the assembly sequence of the radiator device of the third embodiment;

FIG. 31 is an E-E cross sectional view of the perspective view of FIG. 30;

FIG. 32(a) and FIG. 32(b) are views for describing positional adjustment of a heat conductive block of the radiator device of the third embodiment: FIG. 32(a) is an exploded side view of the heat conductive block before positional adjustment is performed; FIG. 32 (b) is a side view of the heat conductive block after positional adjustment is completed;

FIG. 33(a) and FIG. 33(b) are views showing an example in which the radiator device of the third embodiment is connected with a printed board on which an electronic component is mounted: FIG. 33(a) is a cross sectional view; FIG. 33 (b) is an enlarged view of a portion indicated by the alternate long and short dashed lines G in FIG. 33(a);

FIG. 34 (a) through FIG. 34(c) are a top view, a J-J (of FIG. 34(a)) sectional view, and a side view, respectively, of the radiator device according to a fourth embodiment of the present invention;

FIG. 35(a) and FIG. 35(b) are a top view and a side view, respectively, of a heat conductive block of the radiator device of the fourth embodiment;

FIG. 36(a) and FIG. 36(b) are a top view and a side view, respectively, of a radiating board of the radiator device of the fourth embodiment;

FIG. 37 is an exploded perspective view for describing an assembly sequence of the radiator device of the fourth embodiment;

FIG. 38 is an exploded perspective view for describing the assembly sequence of the radiator device of the fourth embodiment;

FIG. 39 is a perspective view for describing the assembly sequence of the radiator device of the fourth embodiment;

FIG. 40(a) and FIG. 40(b) are views for describing a radiating board of a radiator device of the fourth embodiment: FIG. 40(a) is a top view; FIG. 40(b) is a sectional view illustrating a state after positional adjustment of a heat conductive block is completed;

FIG. 41(a) and FIG. 41(b) are views showing an example in which the radiator device of the fourth embodiment is connected with a printed board on which an electronic component is mounted: FIG. 41(a) is a cross sectional view; FIG. 41(b) is an enlarged view of a portion indicated by the alternate long and short dashed lines M in FIG. 41(a);

FIG. 42 is a cross sectional view showing an modified example of a radiator device of the present invention;

FIG. 43 is a perspective view illustrating a conventional communication apparatus;

FIG. 44 is an exploded perspective view illustrating the conventional communication apparatus of FIG. 43;

FIG. 45 is a top view of a plug-in unit for which conventional radiating fins are provided;

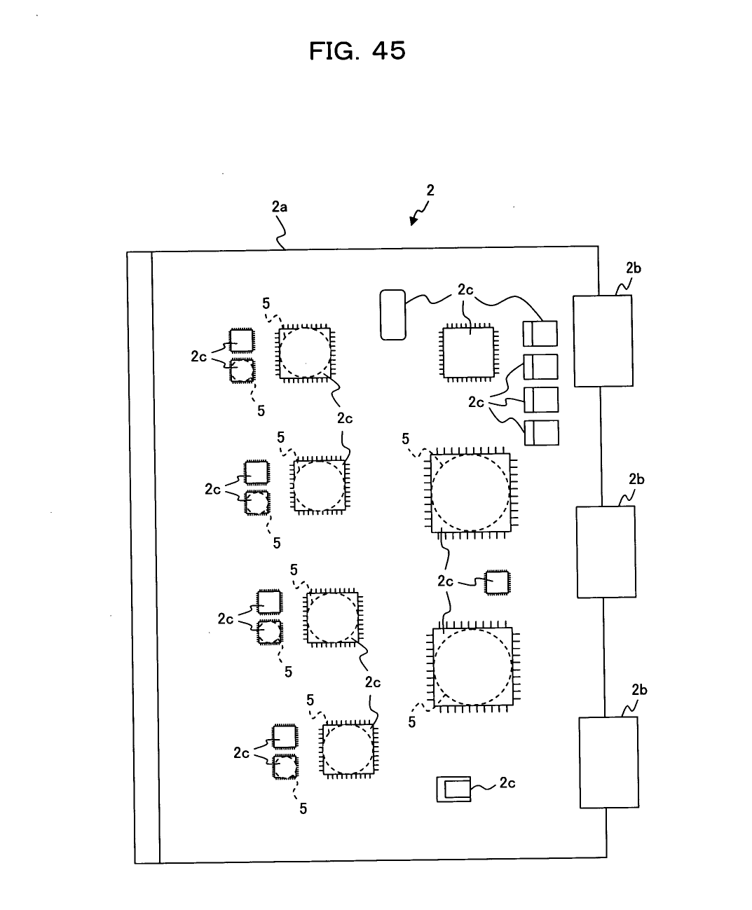

FIG. 46(a) and FIG. 46(b) are a top view and a side view, respectively, of a conventional radiating fin placed over an LSI; and

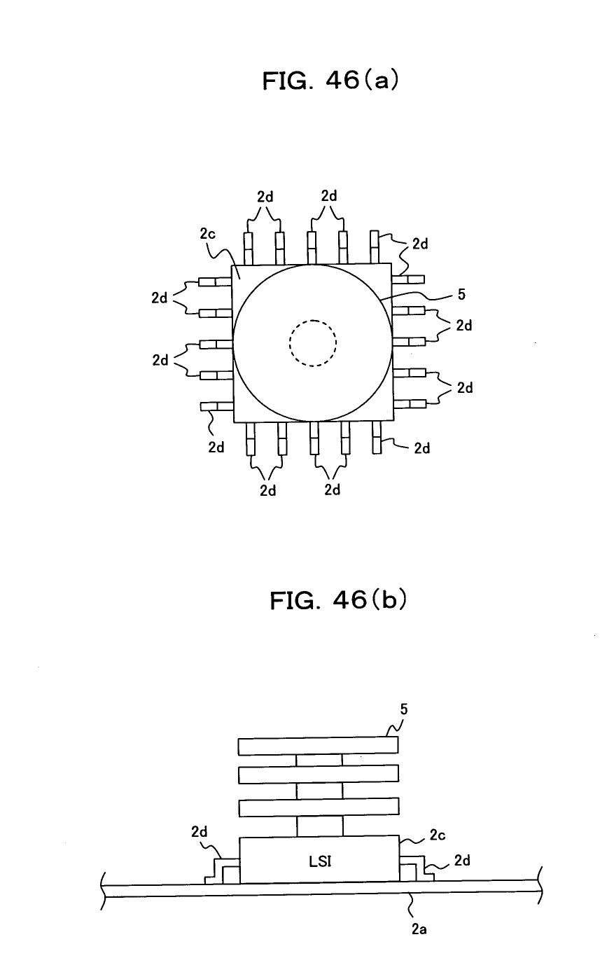

FIG. 47(a) and FIG. 47(b) are a top view and a side view, respectively, of a conventional radiating fin placed over an LSI.

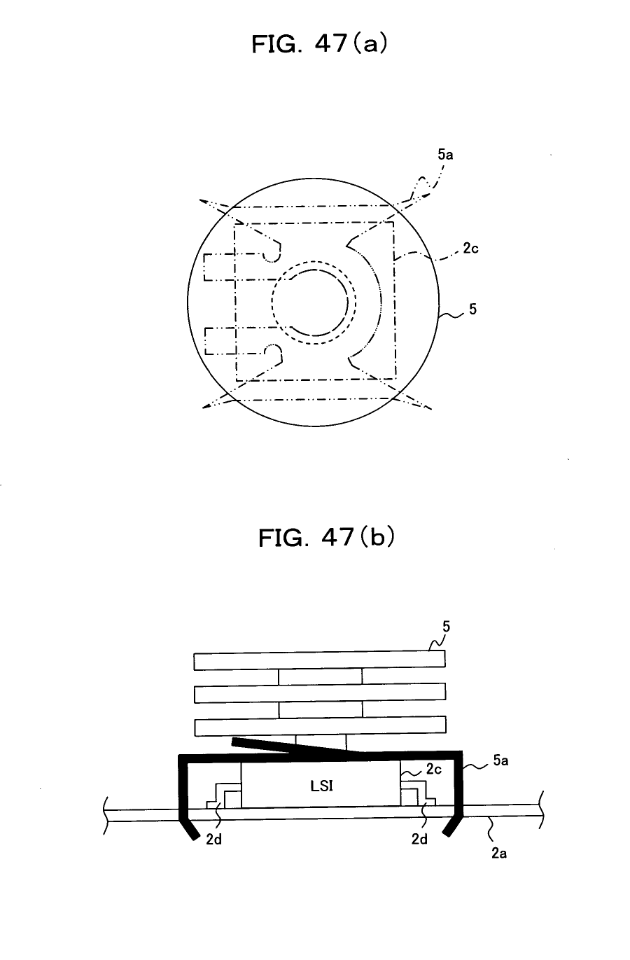

### DESCRIPTION OF THE PREFERRED EMBODIMENT(S)

Preferred embodiments of the present invention will now be described with reference to the relevant accompanying drawings.

### [1] First Embodiment

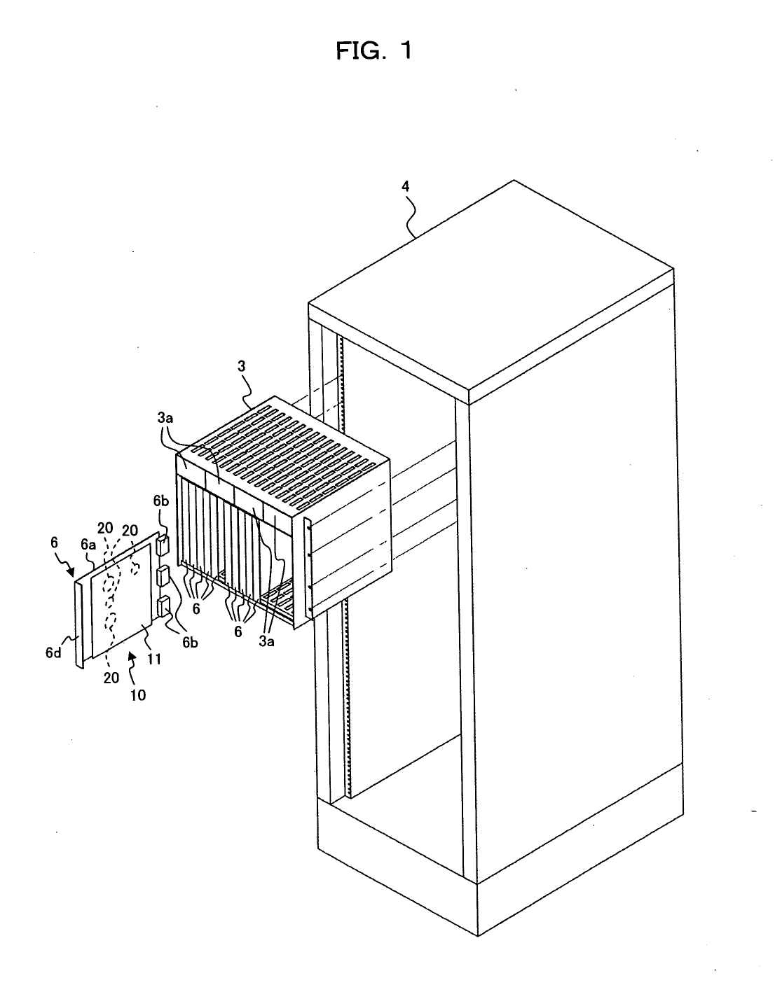

First of all, referring to FIG. 1, a description will be made of a radiator device according to a first embodiment of the present invention. Like reference numbers and characters designate similar parts or elements throughout several views of the present embodiment and the conventional art, so their detailed description is omitted here.

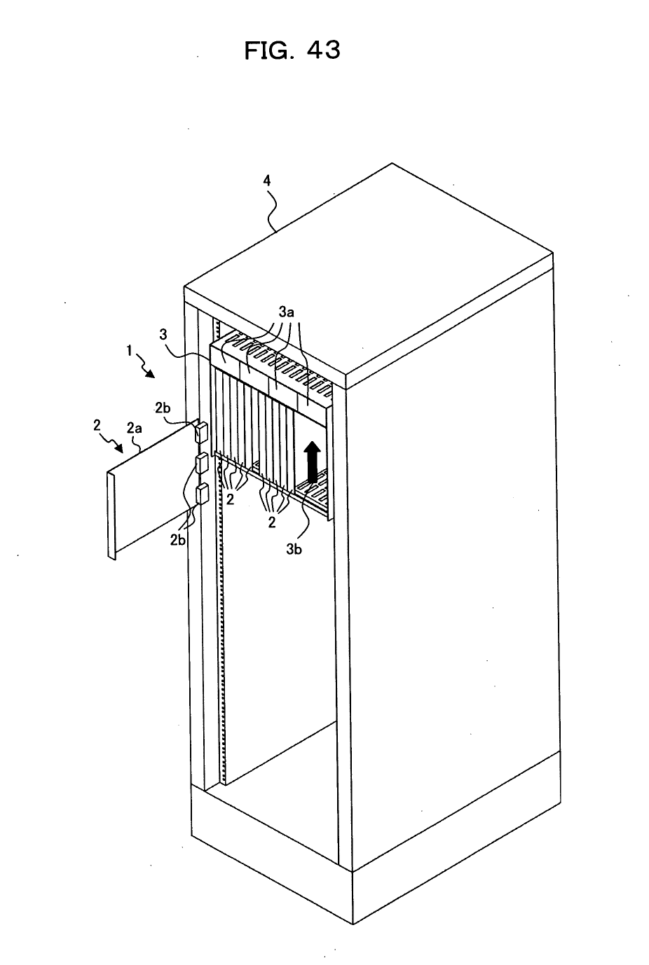

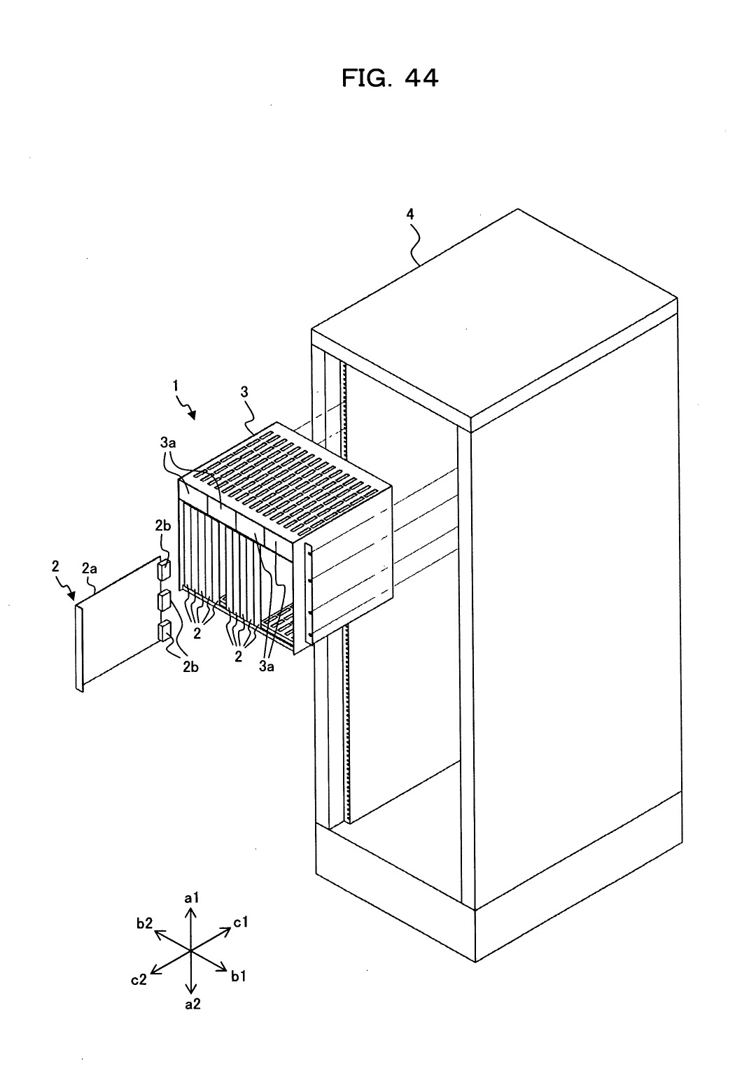

As shown in FIG. 1, like conventional plug-in units of FIG. 43 and FIG. 44, a plug-in unit 6 equipped with a radiator device 10 of the present invention is inserted into a sub-rack 3 which is then mounted in a sub-rack mounting rack 4.

In the plug-in unit 6, a front panel 6d is provided on the front edge of a printed board 6a on which electronic components are mounted, and connectors 6b are provided on the rear edge of the printed board 6a. When the plug-in unit 6 is inserted into the sub-rack 3, connectors 6b are connected to backplane connectors (not shown) provided inside the sub-rack 3, thereby establishing an electric connection between the plug-in unit 6 and the sub-rack 3.

Here, the sub-rack 3 has fans 3a, which have air flow inside the sub-rack 3, and the plug-in units 6 stored in the sub-rack 3 are cooled by the air flow.

Further, as shown in FIG. 1, the radiator device 10 has a radiating board 11 and heat conductive blocks 20.

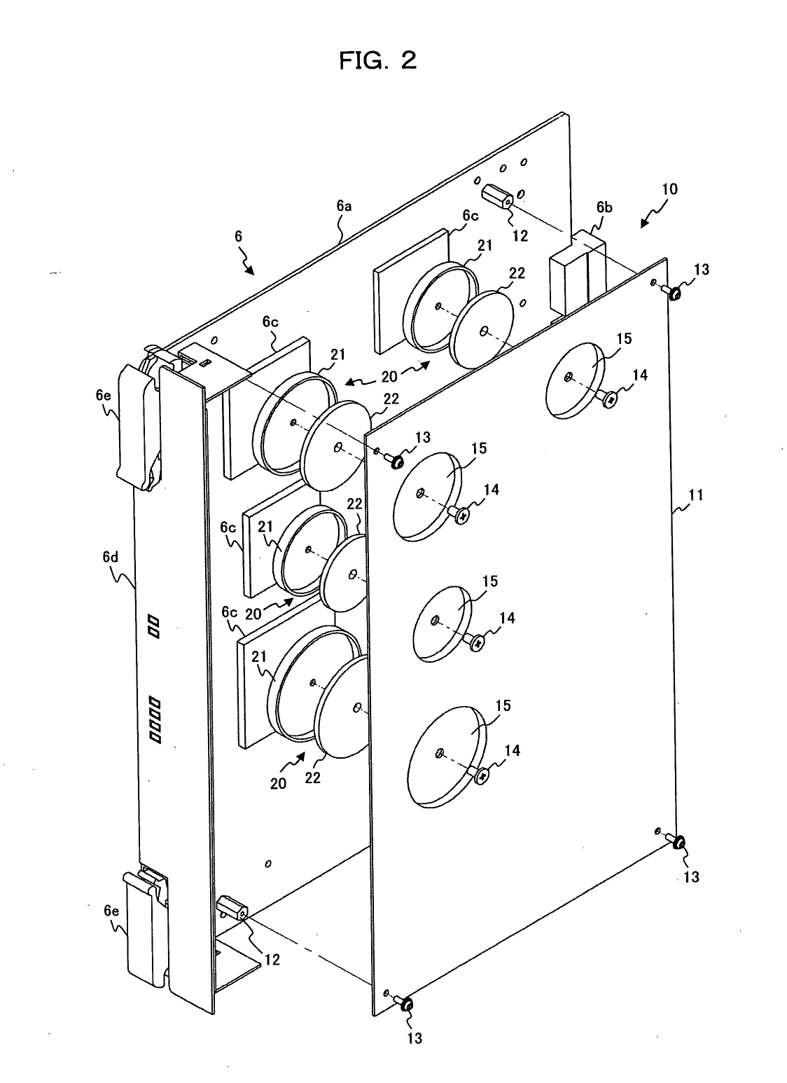

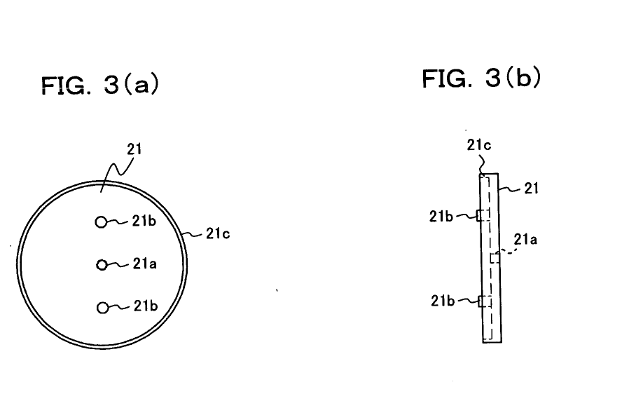

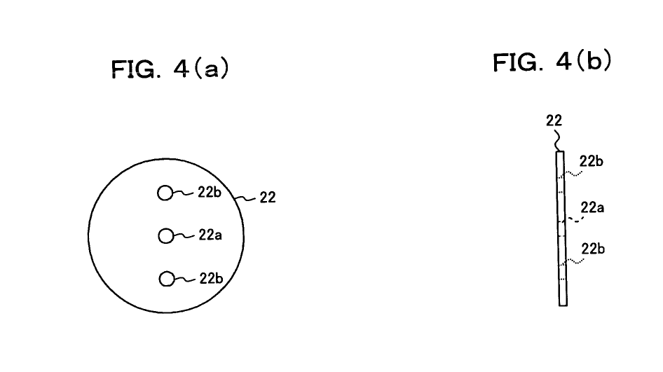

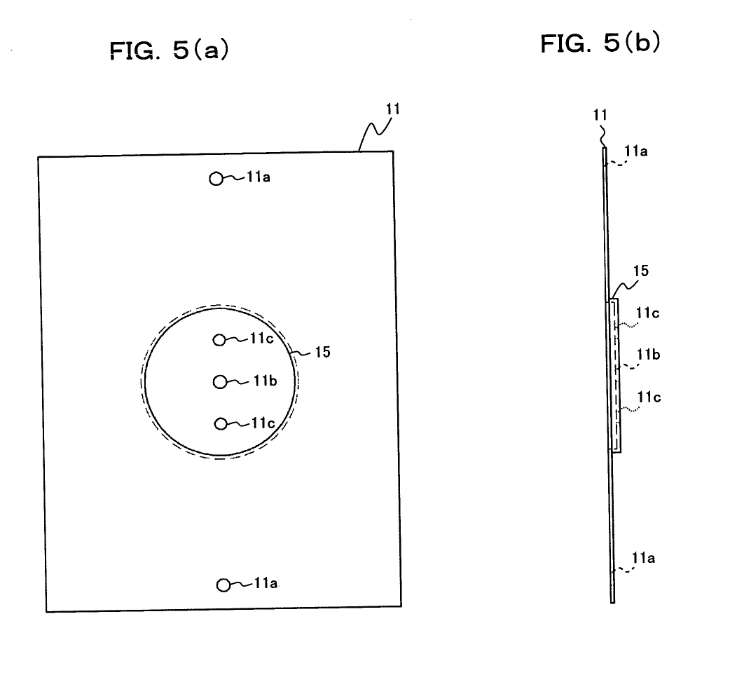

FIG. 2 is an exploded perspective view of the radiator device 10. Card levers 6e equipped to the front panel 6d are used for attaching/detaching the plug-in unit 6 to the sub-rack 3. Further, in FIG. 2, rotation-preventing projections (projections) 21b (see, for example, FIG. 3(a) and FIG. 3(b); will be detailed later) and projection through holes (through holes) 11c and 22b (see, for example, FIG. 5(a), FIG. 5(b), FIG. 4(a), and FIG. 4(b); will be detailed later) are omitted from the illustration for simplification of the illustration.

As shown in FIG. 2, each heat conductive block 20 of the radiator device 10 has a heat conductive member 21 and heat conductive sheet (cushion member) 22, and the heat conductive blocks 20 are provided, one for each of the electronic components 6c (in this example, four heat conductive blocks 20 are provided) at the corresponding positions, so that the heat conductive blocks 20 are attached (connected) to the radiating board 11 while making intimate contact with the electronic components (for example, LSI; Large Scale Integration) 6c.

Further, each heat conductive sheet 22 is interposed between a heat conductive member 21 and the radiating board 11. The heat conductive sheets 22 are sandwiched between the heat conductive members 21 and the radiating board 11, when the heat conductive members 21 are connected with the radiating board 11.

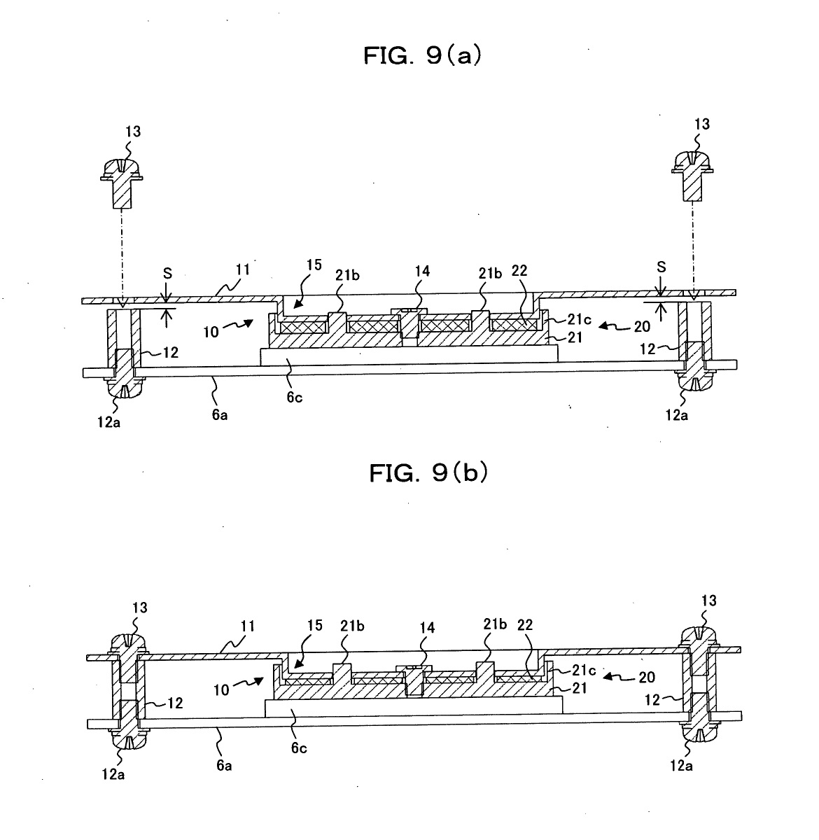

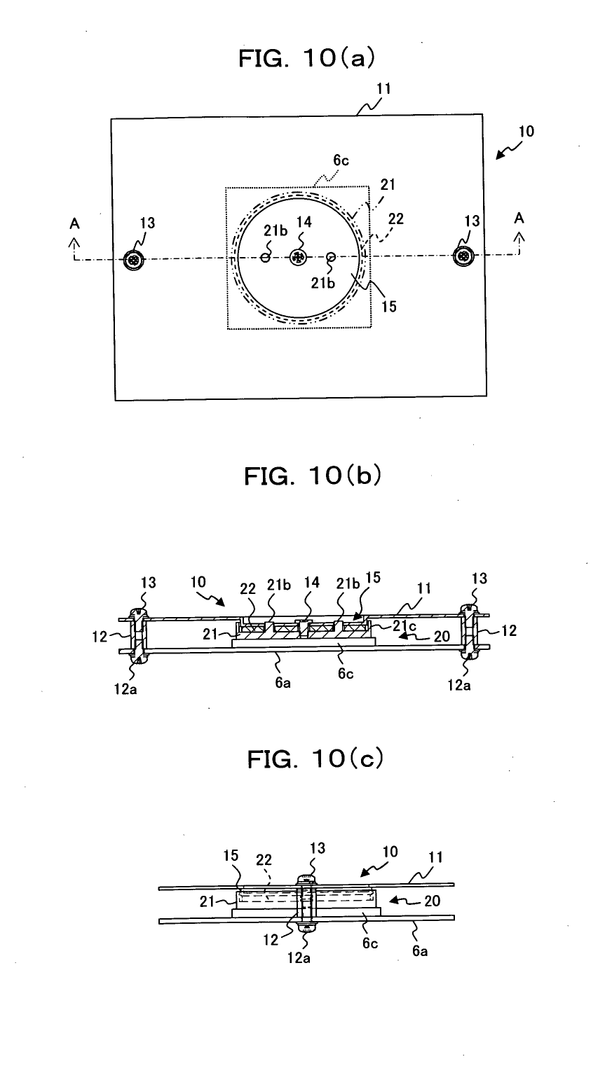

The radiating board 11 is connected with the printed board 6a at its four corners, with spacing bolts 12, which are attached to the printed board 6a, and screws 13. With this arrangement, the radiating board 11 is connected to an electronic component side of the printed board 6a with the spacing bolts 12, leaving a specific space therebetween, and as a result, a space for mounting the heat conductive blocks 20 on the printed board 6a is reserved. Here, mating parts 15 are provided on the radiating board 11 at positions where the heat conductive blocks 20 are to be connected. These mating parts 15 will be detailed later, referring to e.g., FIG. 5(a), FIG. 5(b), FIG. 9(b), and FIG. 10.

The radiating board 11 and the heat conductive block 20 are connected by the engaging screw 14. That is, a tapped hole is provided at the center of the heat conductive member 21, and a tapped hole is also provided for the radiating board 11 at the corresponding position. The engaging screw 14 is screwed into these tapped holes, whereby the radiating board 11 is connected with the heat conductive block 20. As a result, the heat conductive block 20 is connected to a side of the radiating board 11 that faces the printed board 6a, in such manner that the position of the heat conductive block 20 is adjustable along a direction crossing the printed board 6a (preferably, a direction perpendicular to the printed board 6a).

The heat conductive member 21 and the heat conductive sheet 22 of the heat conductive block 20 and the radiating board 11 will be detailed hereinbelow.

As shown in FIG. 3(a) and FIG. 3(b), the heat conductive member 21 has a circular shape and is provided with a tapped hole 21a into which the engaging screw 14 is to be screwed and with one or more (here, two) rotation preventing projections 21b.

Further, the heat conductive member 21 has a wall part 21c on its outside edge so that the heat conductive member 21 forms a concave part relative to the radiating board 11.

The heat conductive member 21 is made of a heat conductive material, and it is preferably made of aluminum, copper, or stainless steel.

As shown in FIG. 4(a) and FIG. 4(b), the heat conductive sheet 22 has a circular shape and has a hole 22a which the engaging screw 14 passes through, and one or more (here, two) through holes 22b which the rotation preventing projections 21b of the heat conductive member 21 pass through.

Further, the heat conductive sheet 22 is formed so that it is accommodated (placed) within the concave part formed by the heat conductive member 21c of the heat conductive member 21. In this example, the heat conductive sheet 22 has a circular shape with a diameter smaller than the diameter of a circle that is formed by the inner face of the heat conductive member 21c.

The heat conductive sheet 22 is made of a material which is not only heat conductive but also compressive (in particular, with respect to the heat conductive member 21), and it is preferably made of elastic rubber, a resin sheet which is made of silicone filled with ceramics filler, or gel resin. Further, the heat conductive sheet 22 is preferably heat resistant.

Next, referring to FIG. 5(a) and FIG. 5(b), a description will be made hereinbelow of the radiating board 11. For simplicity of illustration, only two holes 11a (that is, the connection part with the printed board 6a) which are prepared for the screws 13 that are to be screwed into the spacing bolts 12 attached to the printed board 6a, are illustrated, and also, only one hole 11b and only one mating part 15 are illustrated in the drawings.

Likewise, in the drawings which will be described hereinafter in the present embodiment and in the second through fourth embodiments, for simplicity of illustration, only two connection parts with the printed board 6a are illustrated, and further, only one heat conductive block 20 or only one heat conductive block 23 is illustrated. Note that the number of connections with the printed board 6a and the numbers of heat conductive blocks 20 and heat conductive blocks 23 which are provided, one for each of the electronic components 6c mounted on the printed board 6a, should not be limited.

As shown in FIG. 5(a) and FIG. 5(b), the radiating board 11 has the following: holes 11a which are for connecting the radiating board 11 with the printed board 6a with screws 13, via the spacing bolts 12 interposed therebetween; a tapped hole 11b which is for connecting the radiating board 11 with the heat conductive block 20 (here, heat conductive member 21) with the engaging screw 14; one or more (here, two) projection through holes 11c which one or more (here, two) rotation preventing projections 21b of the heat conductive member 21 pass through; a mating part 15 with a circular shape formed so as to project toward the heat conductive block 20 (that is, the electronic component side of the printed board 6a), which mating part mates with a concave part formed by the heat conductive member 21c of the heat conductive member 21.

The mating part 15 is formed by processing (pressing) the shape of the radiating board 11. The outer size (here, diameter) of the mating part 15 which projects toward the heat conductive block 20 is slightly smaller than the diameter of a circle formed by the inner face of the wall part 21c so that the mating part 15 can mate with the concave part formed by the wall part 21c. When the mating part 15 mates with the concave part formed by the wall part 21c, the outer peripheral surface of the mating part 15 preferably makes intimate contact with the inner peripheral surface of the wall part 21c. Accordingly, the outer size (here, diameter) of the mating part 15 is preferably approximately the same as the inner size (here, diameter) of the concave part formed by the wall part 21c.

In this manner, the mating part 15 mates with the concave part, with its outer peripheral surface making intimate contact with the inner peripheral surface of the wall part 21c. This arrangement makes it possible to transfer heat, which has been transferred from the electronic components 6c to the heat conductive member 21, to the mating part 15 (that is, the radiating board 11) via the wall part 21c, whereby the heat radiation efficiency of the radiator device 10 is improved.

In addition, since the radiating board 11 is processed so that it has the mating part 15, as a concave part, on its upper surface, the upper portion of the engaging screw 14 and the upper edge of the rotation preventing projections 21b are prevented from projecting beyond the upper surface of the radiating board 11, so that the height of the whole radiator device 10 is reduced. Therefore, even if the height of the plug-in unit 6 is limited, the radiator device 10 is applicable.

Here, the radiating board 11 is made of a heat conductive material, and it is preferably made of aluminum, copper or stainless steal.

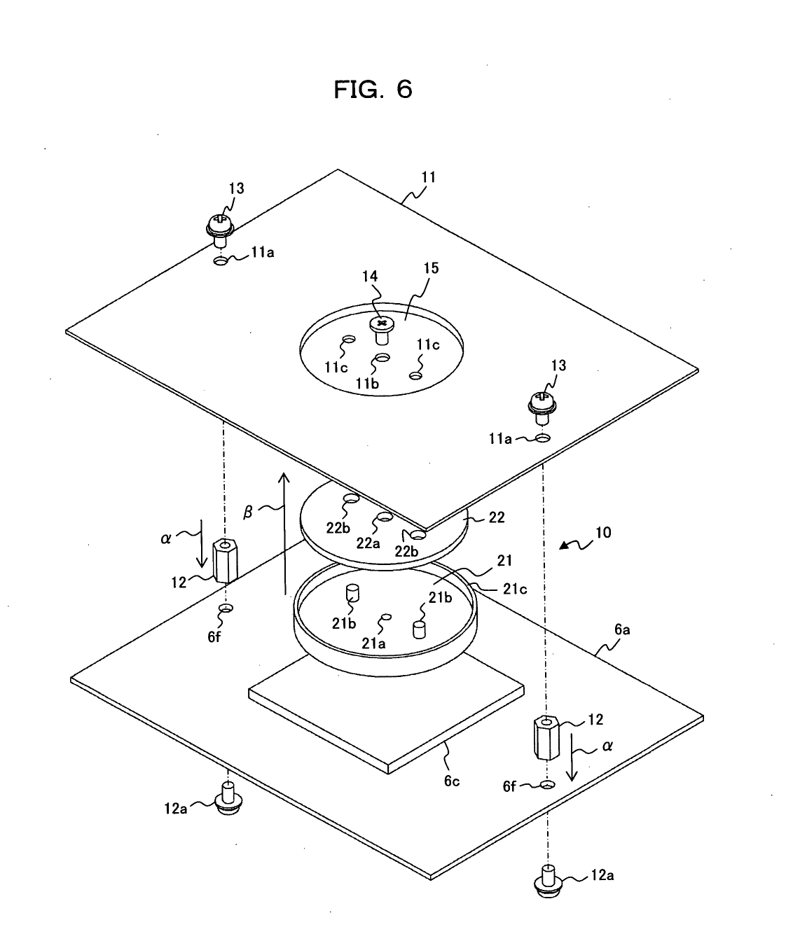

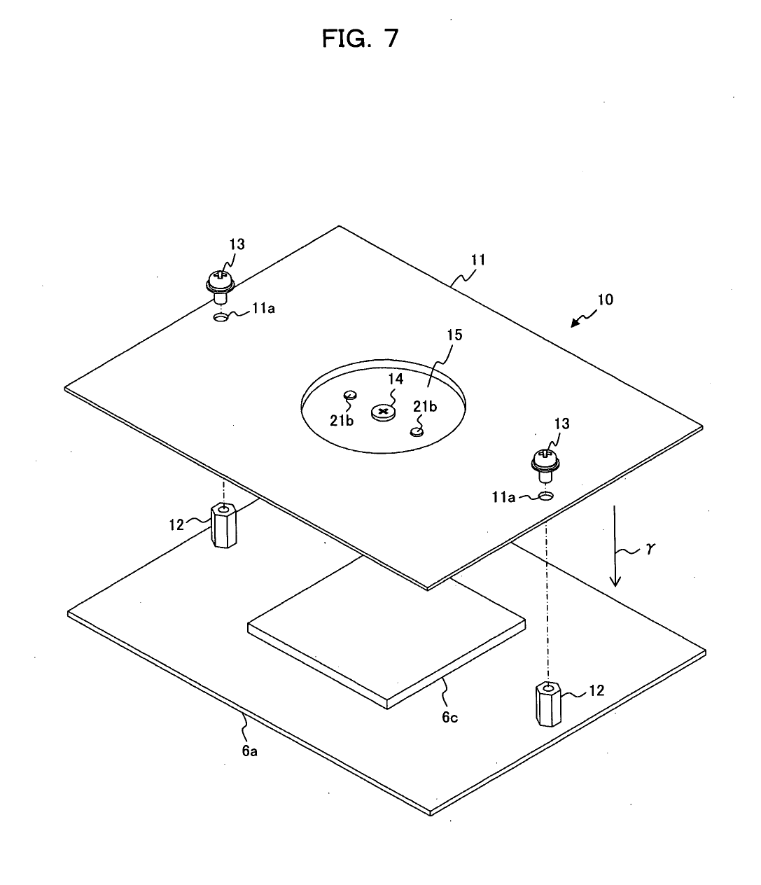

Next, referring to FIG. 6 through FIG. 8, an assembly sequence of the radiator device 10 (heat conductive member 21, heat conductive sheet 22, and radiating board 11) will be described hereinbelow. In the beginning, as indicated by arrow α in FIG. 6, the screws 12a are put into the holes 6f from the bottom of the printed board 6a, and pass through the holes 6f, and are screwed into the spacing bolts 12, whereby the spacing bolts 12 are fastened to the printed board 6a (see FIG. 7).

Further, as indicated by arrow β, the engaging screw 14 is put into the tapped hole 11b from the upper surface of the radiating board 11, and passes through the hole 22a of the heat conductive sheet 22, and is crewed into the tapped hole 21a of the heat conductive member 21, whereby the radiating board 11 is connected with the heat conductive member 21 (see FIG. 7). In this case, the rotation preventing projections 21b of the heat conductive member 21 pass through the projection through holes 22b of the heat conductive sheet 22 and the projection through holes 11c of the radiating board 11, whereby rotation of the heat conductive member 21 is prevented, so that deviation of the position of the heat conductive member 21 relative to the radiating board 11 is also prevented.

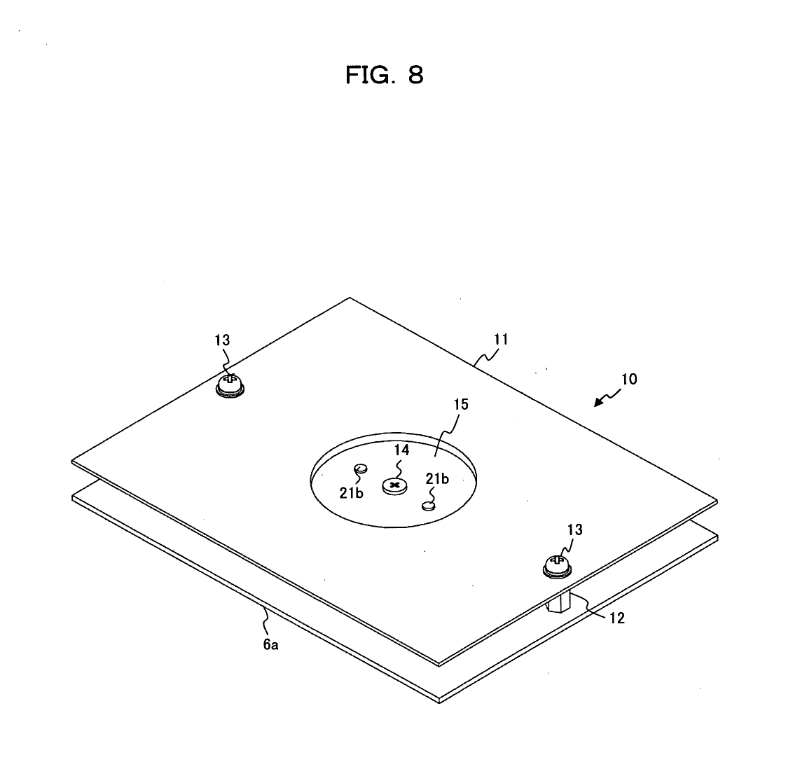

Furthermore, as indicated by arrow γ in FIG. 7, the screws 13 are put into the holes 11a of the radiating board 11 from the upper surface of the radiating board 11, and pass through the holes 11a, and are screwed into the spacing bolts 12, whereby the printed board 6a and the radiating board 11, which is connected with the heat conductive block 20, are connected (see FIG. 8).

In this case, as shown in FIG. 9(a), even if gaps S are present between the spacing bolts 12 and the radiating board 11 under a condition where the heat conductive member 21 makes intimate contact with the electronic component 6c, the heat conductive sheet 22 is compressed as shown in FIG. 9(b) (because the heat conductive sheet 22 is compressible), so that the radiating board 11 is completely connected with the spacing bolts 12 and with the screws 13.

Here, if the heat conductive sheet 22 is compressed in a direction crossing the printed board 6a, the heat conductive sheet 22 spreads in the lateral direction. However, due to the wall part 21c of the heat conductive member 21, the laterally spreading heat conductive sheet 22 is prevented from overlapping the edge of the heat conductive member 21 and from hanging down over the electronic component 6c.

When the heat conductive sheet 22 is compressed, pressure of the radiating board 11 against the printed board 6a, caused by the screws 13 screwed into the spacing bolts 12, is uniformly transferred to the heat conductive member 21, and as a result, the heat conductive member 21 uniformly makes intimate contact with the electronic component 6c. That is, the electronic component 6c and the heat conductive member 21 make intimate contact with each other with equal force at any part thereof.

If the gaps S are not removed only by compressing the heat conductive sheet 22, the engaging screw 14 is further tightened, thereby adjusting the position of the heat conductive member 21 so as to be closer to the radiating board 11. This makes it possible to remove the gaps S so that the radiating board 11 is completely connected with the spacing bolts 12.

Further, adjustment of the engaging screw 14 makes it possible to control the contact between the heat conductive member 21 and the electronic component 6c, so that the heat conductive member 21 can be adjusted to an optimal contact height. Accordingly, it is possible to reliably prevent the heat conductive member 21 from pressing the electronic component 6c so strongly that the electronic component 6c is broken.

If the heat conductive member 21 does not make intimate contact with the corresponding electronic component 6c, with the radiating board 11 being connected to the spacing bolts 12 with the screws 13, the engaging screw 14 is loosened, thereby realizing intimate contact between the heat conductive member 21 and the electronic component 6c.

In this manner, the printed board 6a is connected with the radiating board 11 to which the heat conductive block 20 is attached. As a result, as shown in FIG. 10(a) through FIG. 10(c), the radiator device 10 is connected with the printed board 6a, with the heat conductive member 21 making intimate contact with the electronic component 6c mounted on the printed board 6a.

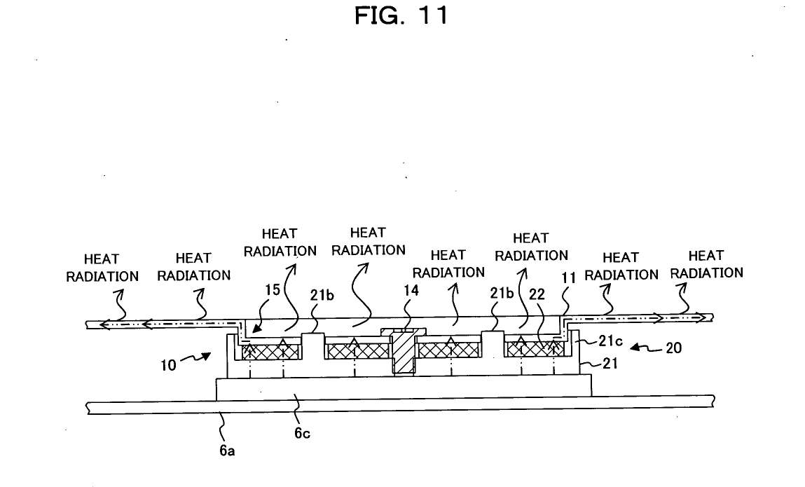

FIG. 11 is an enlarged view of FIG. 10(b), which is an A-A cross sectional view of FIG. 10(a). In FIG. 11, the two-dotted lines arrow indicates transfer of heat (heat flow) generated by the electronic component 6c.

As shown in FIG. 11, according to the radiator device 10, since the heat conductive member 21, the heat conductive sheet 22, and the radiating board 11 (mating part 15) possess heat conductivity, heat generated by the electronic component 6c mounted on the printed board 6a is transferred to the heat conductive member 21, the heat conductive sheet 22, and the radiating board 11 (mating part 15), in this order, and is then radiated outside.

In this manner, according to the radiator device 10 of the first embodiment of the present invention, the heat generated by the electronic components 6c mounted on the printed board 6a is transferred to the radiating board 11 via the heat conductive block 20 which makes intimate contact with the upper surface of the electronic components 6c, so that a high heat radiation efficiency is realized.

What is more, since the heat conductive sheet 22 interposed between the mating part 15 of the radiating board 11 and the heat conductive member 21 is compressed by connecting the radiating board 11 and the heat conductive member 21, the pressure against the printed board 6a is evenly transferred to the heat conductive member 21, so that the heat conductive member 21 makes even contact with the electronic component 6c. This increases the heat conductivity from the electronic component 6c to the heat conductive member 21, thereby realizing a high heat radiation efficiency.

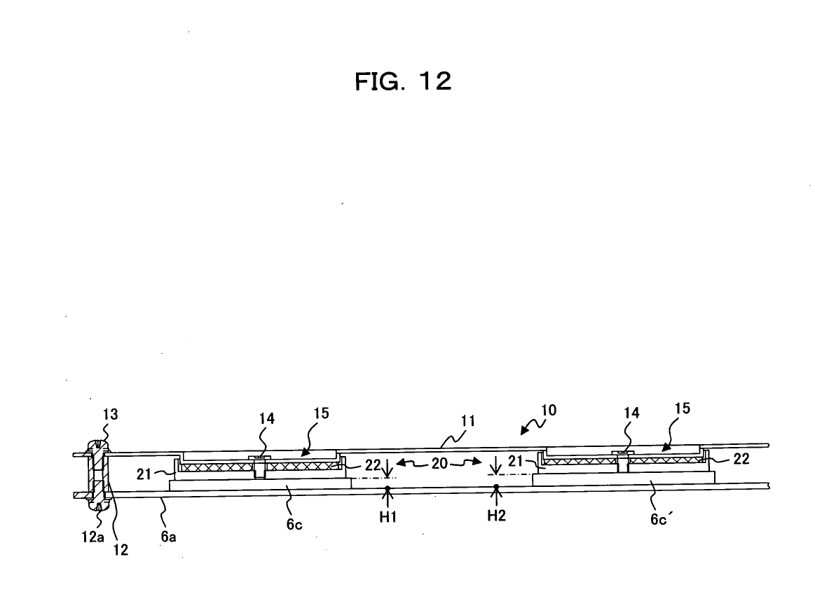

Further, as shown in FIG. 12, even if two or more (in this example, two) electronic components 6c and 6c′ mounted on the printed board 6a have different heights (here, H1<H2 where H1 is the height of the electronic component 6c and H2 is the height of the electronic component 6c′), the position of the heat conductive block 20 in the height direction can be easily adjusted, so that an error in height between the electronic components 6c and 6c′ can be reliably absorbed. This is because the position of the heat conductive member 21 is adjustable along a direction crossing the printed board 6a by adjusting the engaging screw 14, and also because the heat conductive sheet 22 is compressible.

Further, since an error in height among the electronic components 6c and 6c′, can be reliably absorbed, heat radiation of the electronic components 6c and 6c′ can be equalized.

Even if a necessity arises of checking the model number or the manufacturer's name of an electronic component 6c, which information is described on the upper surface of the electronic component 6c, for modification or repair to be added to the printed board 6a, it is possible to remove the radiator device 10 from the printed board 6a only by removing the screws 13 which are screwed into the spacing bolts 12 on the radiating board 11. Thus, the model number and the manufacturer's name described on the printed board 6a can be easily recognized.

### [2] Second Embodiment

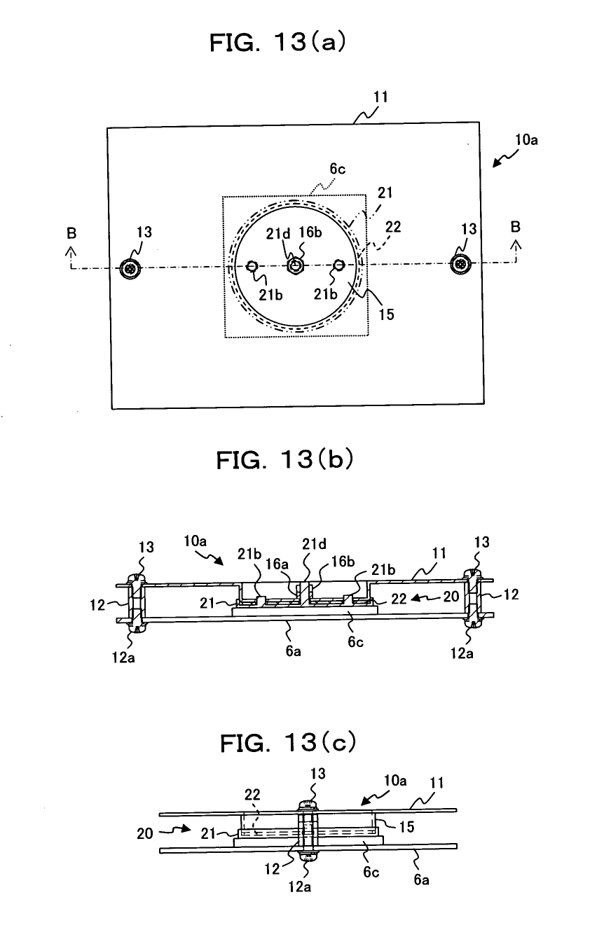

Next, referring to FIG. 13(a) through FIG. 13(c), a description will be made of a radiator device according to a second embodiment of the preset invention. Like reference numbers and characters designate similar parts or elements throughout several views of the present embodiment and the conventional art, so their detailed description is omitted here.

In contrast to the radiator device 10 of the first embodiment, in which the heat conductive block 20 is connected by the engaging screw 14 with a side of the radiating board 11 that faces the printed board 6a, in the radiator device 10a, as shown in FIG. 13(a) through FIG. 13(c), the heat conductive member 21 has a male screw 21d extending toward the radiating board 11. The male screw 21d passes through the heat conductive sheet 22 and the radiating board 11 (here, mating part 15). By screwing an adjustment nut 16a and a lock nut 16b onto the male screw 21d on the upper surface of the radiating board 11, the heat conductive block 20, including the heat conductive member 21 and the heat conductive sheet 22, is connected with a side of the radiating board 11 that faces the printed board 6a in such a manner that the position of the heat conductive block 20 is adjustable in relation to the printed board 6a. Except for these differences, construction of the radiator device 10a is similar to the radiator device 10. Accordingly, in the following description, only parts of the radiator device 10a different from the radiator device 10 of the first embodiment will be described, and a detailed description of parts of the radiator device 10a similar to the radiator device 10 will be omitted.

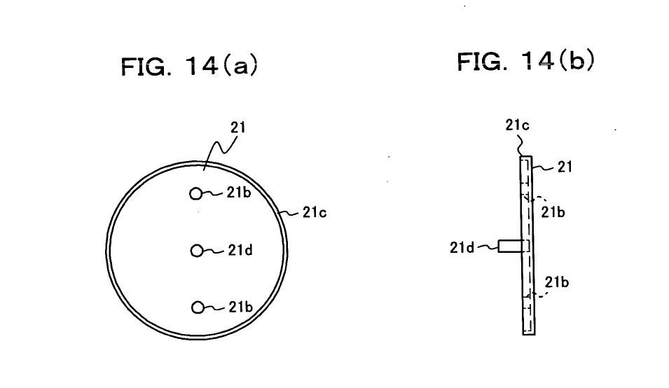

That is, as shown in FIG. 14(a) and FIG. 14(b), the heat conductive member 21 of the radiator device 10a has a male screw 21d. The male screw 21d is placed at the center of the radiator device 10a and extends toward the radiating board 11. Here, the male screw 21d is preferably provided perpendicularly to the radiating board 11, whereby the position of the heat conductive member 21 can be adjusted along a direction perpendicular to the radiating board 11.

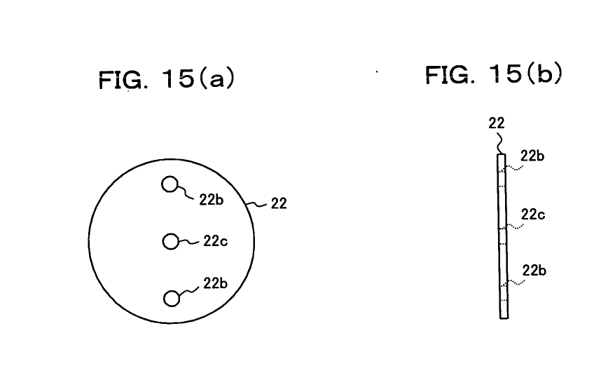

As shown in FIG. 15(a) and FIG. 15(b), the heat conductive sheet 22 of the radiator device 10a has a through hole 22c for letting the male screw 21d pass therethrough.

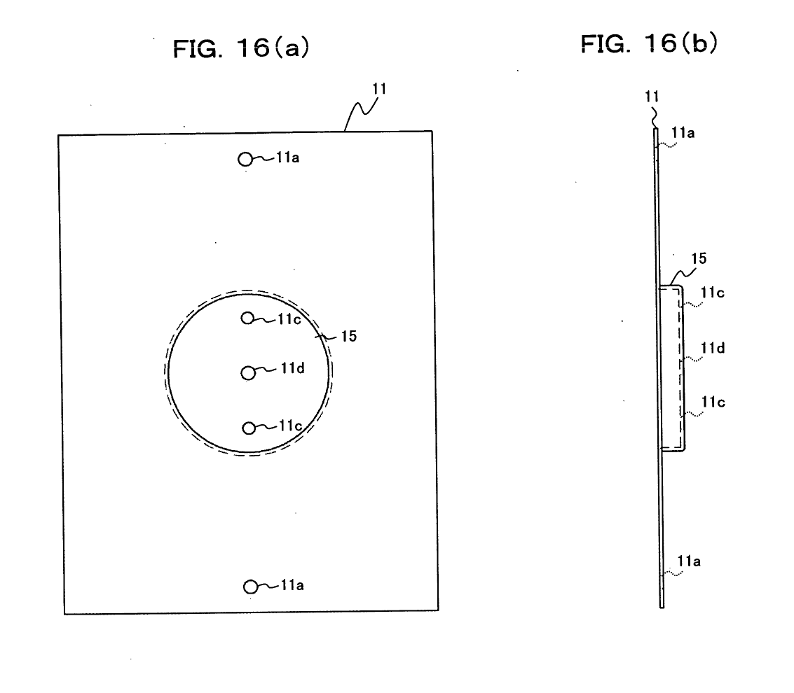

Further, as shown in FIG. 16(a) and FIG. 16(b), the mating part 15 of the radiating board 11 of the radiator device 10a has a through hole lid which the male screw 21d passes through.

By processing the radiating board 11 so as to have the mating part 15 as a concave part on the upper surface of the radiating board 11, it is possible to prevent the upper edge of the male screw 21d of the heat conductive member 21 from projecting beyond the upper surface of the radiating board 11, so that the height of the whole radiator device 10a is reduced. Thus, the radiator device 10a is applicable in cases where the height of the plug-in unit 6 is limited.

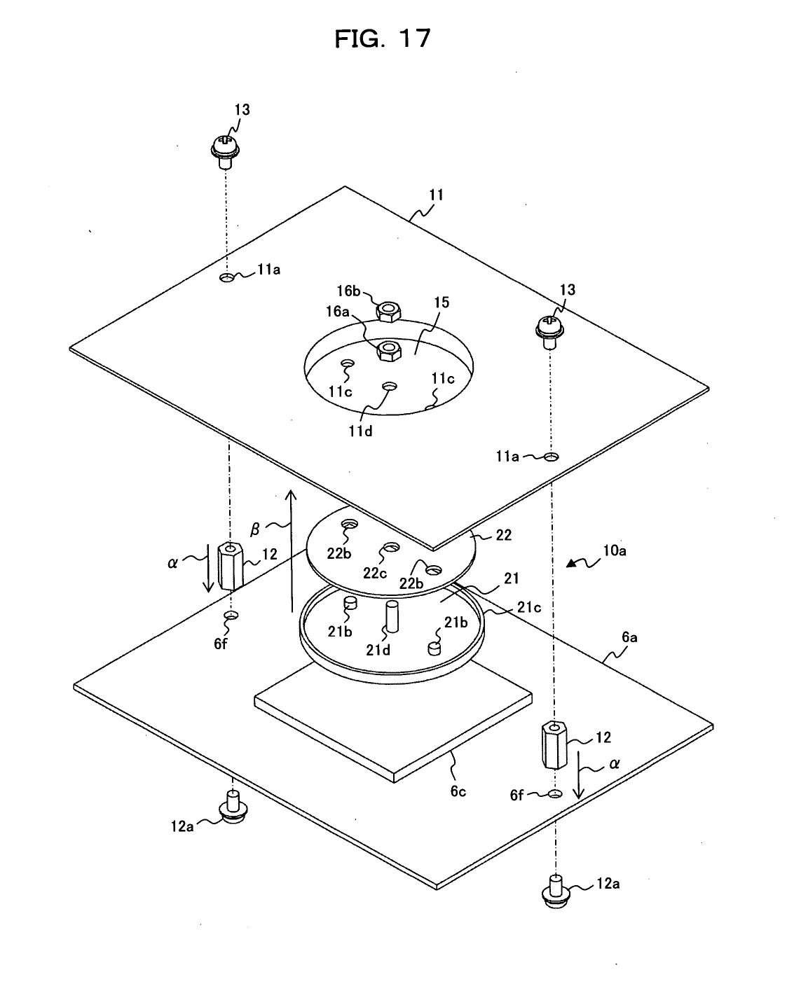

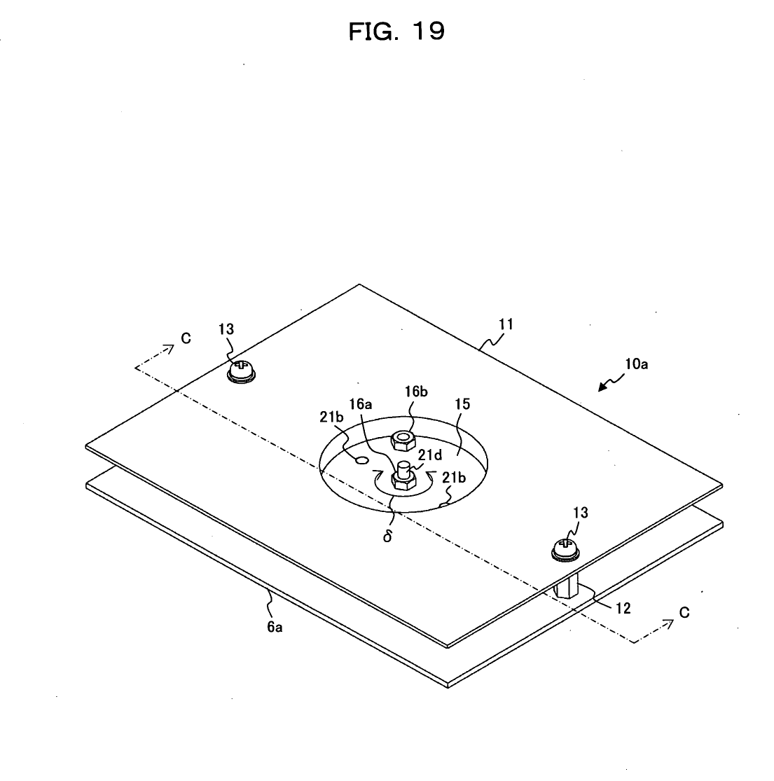

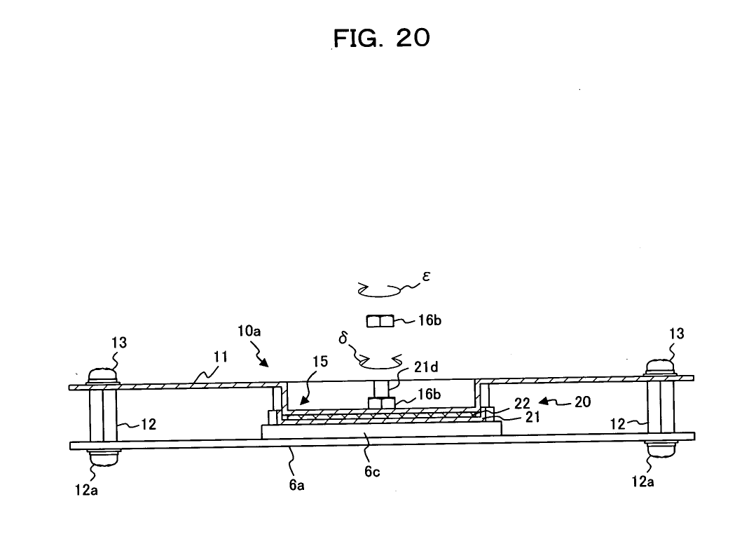

Now, referring to FIG. 17 through FIG. 20, an assembly sequence of the radiator device 10a (heat conductive member 21, heat conductive sheet 22, and radiating board 11) will be described. FIG. 20 is a C-C cross sectional view of FIG. 19.

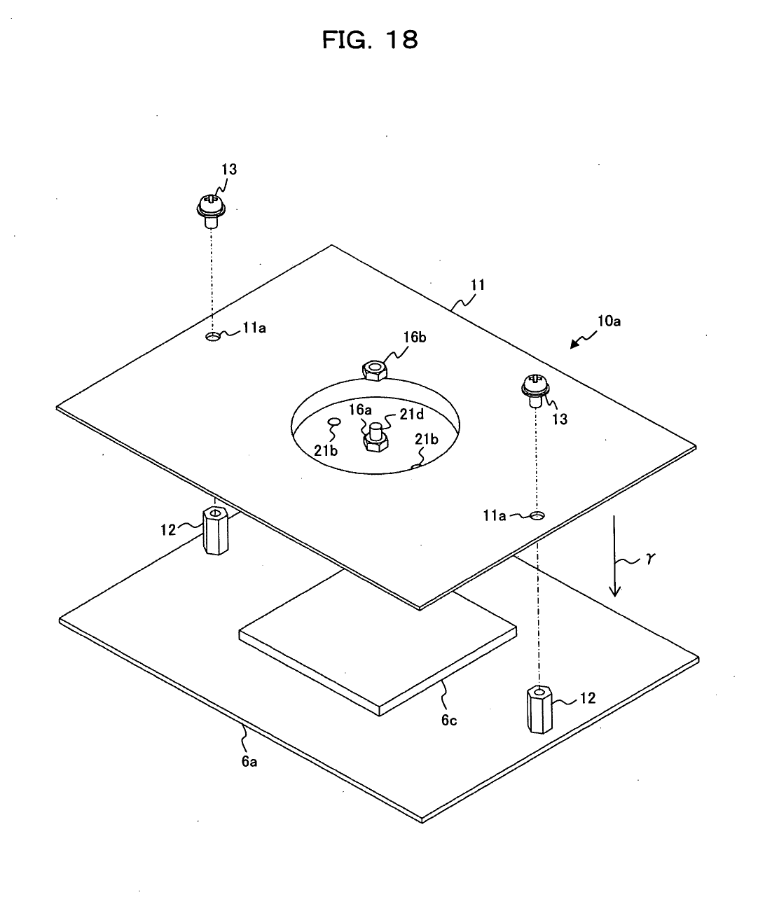

First of all, as indicated by arrow α in FIG. 17, the printed board 6a and the spacing bolts 12 are connected with the screws 12a (see FIG. 18).

Further, as indicated by arrow β, the male screw 21d of the heat conductive member 21 passes through the through hole 22c of the heat conductive sheet 22, and also passes through the through hole lid of the radiating board 11, and projects beyond the upper surface of the radiating board 11. The adjustment nut 16a is screwed onto the projecting male screw 21d, whereby the heat conductive block 20 is connected with the radiating board 11 (see FIG. 18). In this case, the rotation preventing projections 21b of the heat conductive member 21 pass through the projection through holes 22b of the heat conductive sheet 22 and the projection through holes 11c of the radiating board 11 (see FIG. 18).

Then, as indicated by arrow γ in FIG. 18, the radiating board 11 is connected with the spacing bolts 12, whereby the printed board 6a is connected with the radiating board 11 to which the heat conductive block 20 is connected (see FIG. 19 and FIG. 20).

Subsequently, by adjusting the adjustment nut 16a as indicated by arrow δ in FIG. 19, the position of the heat conductive block 20 connected to the radiating board 11 is adjusted so that the heat conductive block 20 has an optimum contact height with respect to the electronic components 6c. After that, as shown by arrow ε in FIG. 20, the lock nut 16b is screwed onto the male screw 21d. By screwing this lock nut 16b onto the adjustment nut 16a, it is possible to prevent the adjustment nut 16a from being loosened.

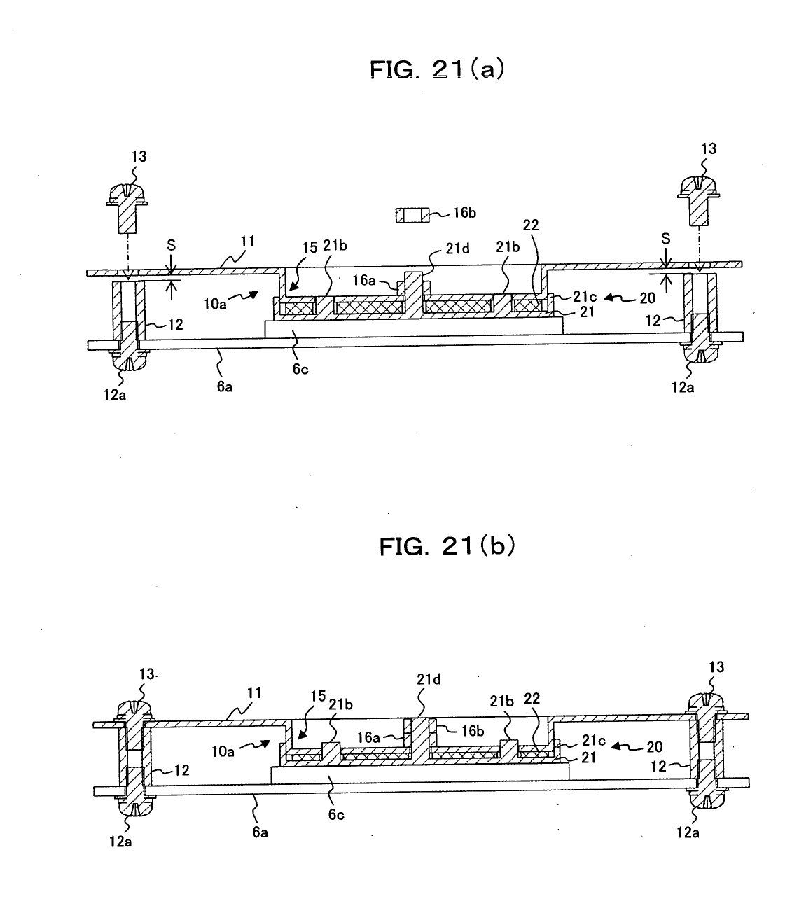

That is, when gaps S are present between the spacing bolts 12 and the radiating board 11 under a condition where the heat conductive member 21 makes intimate contact with the electronic components 6c, as shown in FIG. 21(a), the adjustment nut 16a is tightened, as shown in FIG. 21(b), so that the heat conductive block 20 becomes closer to the radiating board 11. This makes it possible to remove the gaps S, thereby completely connecting the radiating board 11 to the spacing bolts 12. In this instance, by compressing the heat conductive sheet 22, it is possible to adjust the position of the heat conductive member 21.

If the heat conductive member 21 does not make intimate contact with the corresponding electronic component 6c under a condition where the radiating board 11 is connected to the spacing bolts 12 with the screws 13, the adjustment nut 16a can be loosened to realize intimate contact between the heat conductive member 21 and the electronic component 6c.

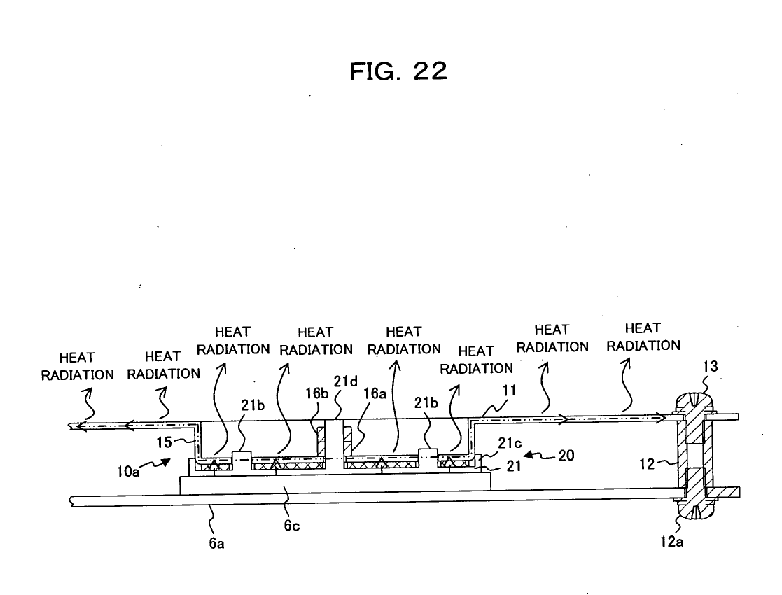

Accordingly, as shown in FIG. 22, as with the radiator device 10 of the first embodiment, in the radiator device 10a, since the heat conductive member 21, the heat conductive sheet 22, and the radiating board 11 (mating part 15) possess heat conductivity, heat generated by the electronic component 6c mounted on the printed board 6a is transferred to the heat conductive member 21, the heat conductive sheet 22, and the radiating board 11 (mating part 15), in this order, and is then radiated outside. Here, in FIG. 22, the two-dotted lines arrow indicates transfer of heat (heat flow) generated by the electronic component 6c.

In this manner, the radiator device 10a of the second embodiment of the present invention realizes like effects and benefits to those of the first embodiment.

### [3] Third Embodiment

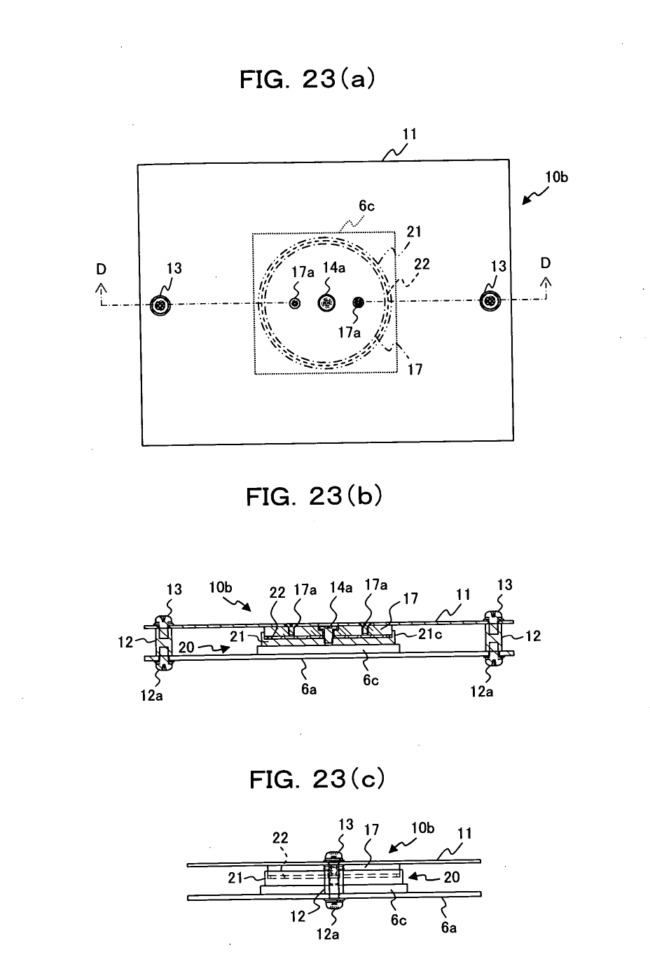

Next, referring to FIG. 23(a) through FIG. 23(c), a description will be made of a radiator device according to a third preferred embodiment of the present invention. Like reference numbers and characters designate similar parts or elements throughout several views of the present embodiment and the conventional art, so their detailed description is omitted here.

In contrast to the radiator device 10 of the first embodiment, in which the mating part 15 is formed by processing the shape of the radiating board 11, in the radiator device 10b of the third embodiment, as shown in FIG. 23(a) through FIG. 23(c), the mating part 17 is formed as a member other than the radiating board 11, and the mating part 17 is connected to the heat conductive block 20 with the engaging screw (fall-off preventing screw) 14a, and the mating part 17 to which the heat conductive block 20 is attached is connected to the radiating board 11 with more than one (here, two) screw 17a. Accordingly, in the following description, only parts of the radiator device 10b different from the radiator device 10 of the first embodiment will be described, and a detailed description of parts of the radiator device 10b similar to the radiator device 10 will be omitted.

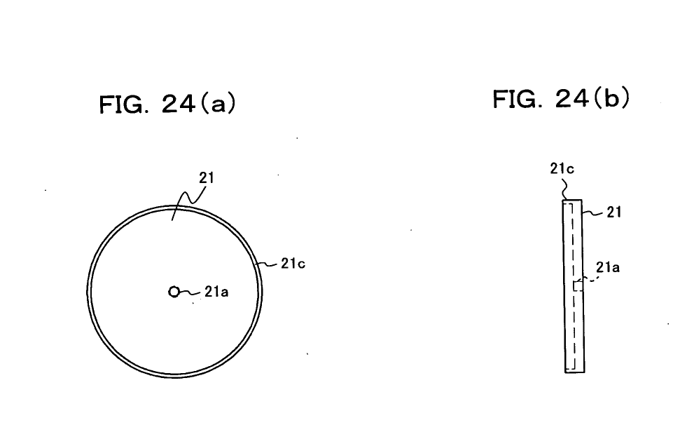

That is, as shown in FIG. 24(a) and FIG. 24(b), the heat conductive member 21 of the radiator device 10b has a tapped hole 21a, into which the engaging screw 14a is screwed, at its center, and the wall part 21c. In the radiator device 10b, rotation preventing projections 21b are not provided for the heat conductive member 21.

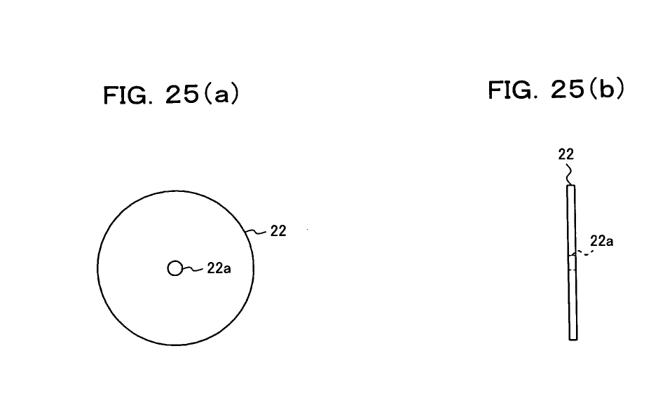

In addition, as shown in FIG. 25(a) and FIG. 25(b) the heat conductive sheet 22 of the radiator device 10b has a hole 22a which the engaging screw 14a passes through.

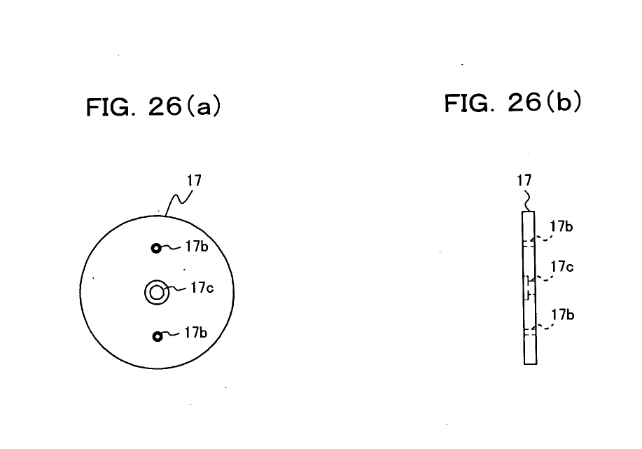

Further, as shown in FIG. 26(a) and FIG. 26(b), the mating part 17 of the radiator device 10b has more than one (here, two) tapped hole 17b into which more than one screw 17a is screwed for connection with the radiating board 11, and has a countersunk hole 17c for connection with the heat conductive block 20 (here, heat conductive member 21) by means of the engaging screw 14.

Here, the mating part 17 is made of a heat conductive material. It is preferably made of aluminum, copper, or stainless steel.

Since the mating part 17 and the radiating board 11 are connected by means of more than one screw 17a, displacement between the mating part 17 and the heat conductive block 20 connected to the mating part 17 is prevented.

Further, as with the mating part 15 of the radiator device 10 of the first embodiment, when the mating part 17 is mated with the heat conductive member 21, the outer peripheral surface of the mating part 17 makes intimate contact with the inner surface of the concave part formed by the wall part 21c of the heat conductive member 21. Accordingly, the outer size (here, diameter) of the mating part 17 is preferably the same or approximately the same as the inner size (here, diameter) of the concave part formed by the wall part 21c.

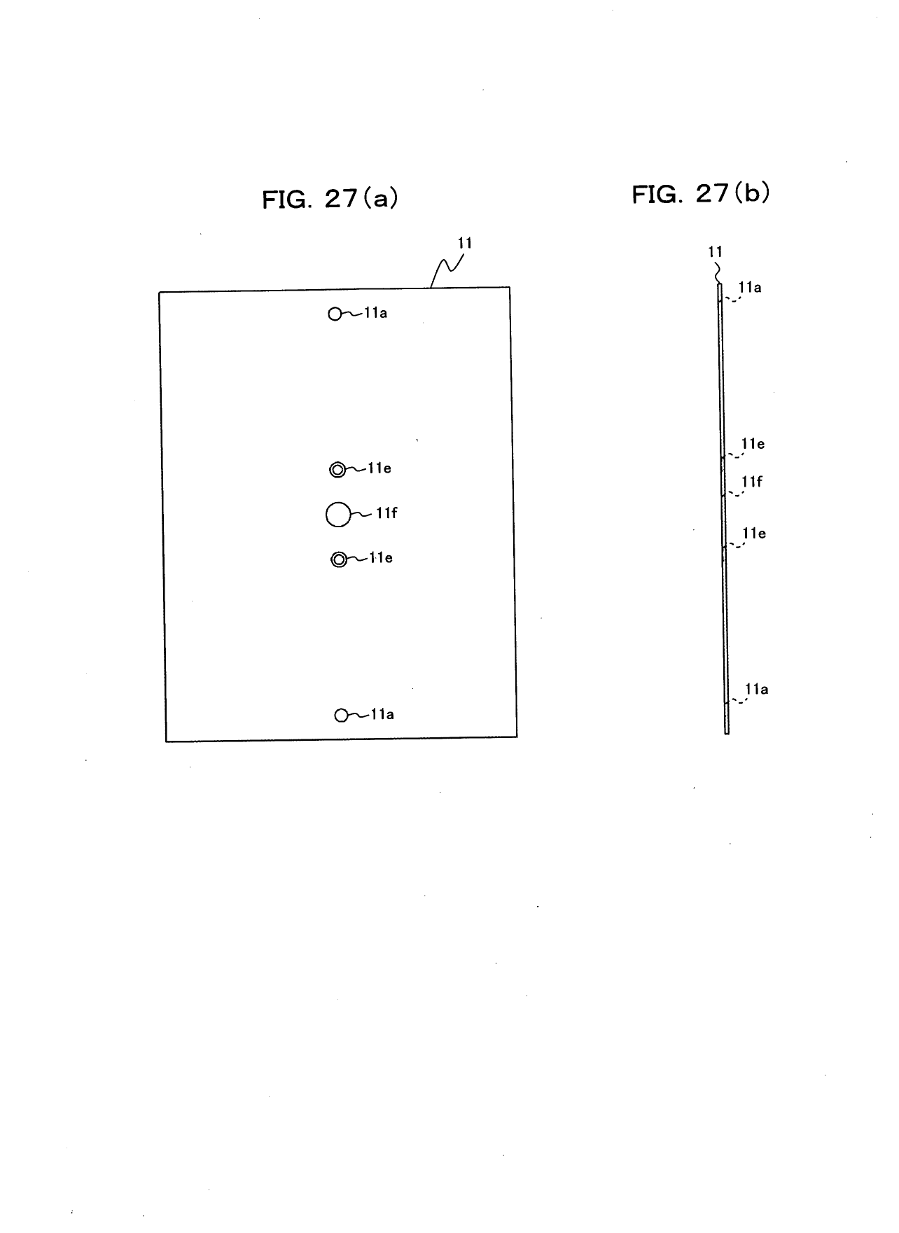

As shown in FIG. 27(a) and FIG. 27(b), the radiating board 11 of the radiator device 10b has more than one (here, two) hole lie for connecting the mating part 17 by means of more than one (here, two) screw 17a, and also has a hole 11f for exposing the upper surface of the engaging screw 14a, which is for connecting the mating part 17 and the heat conductive member 21.

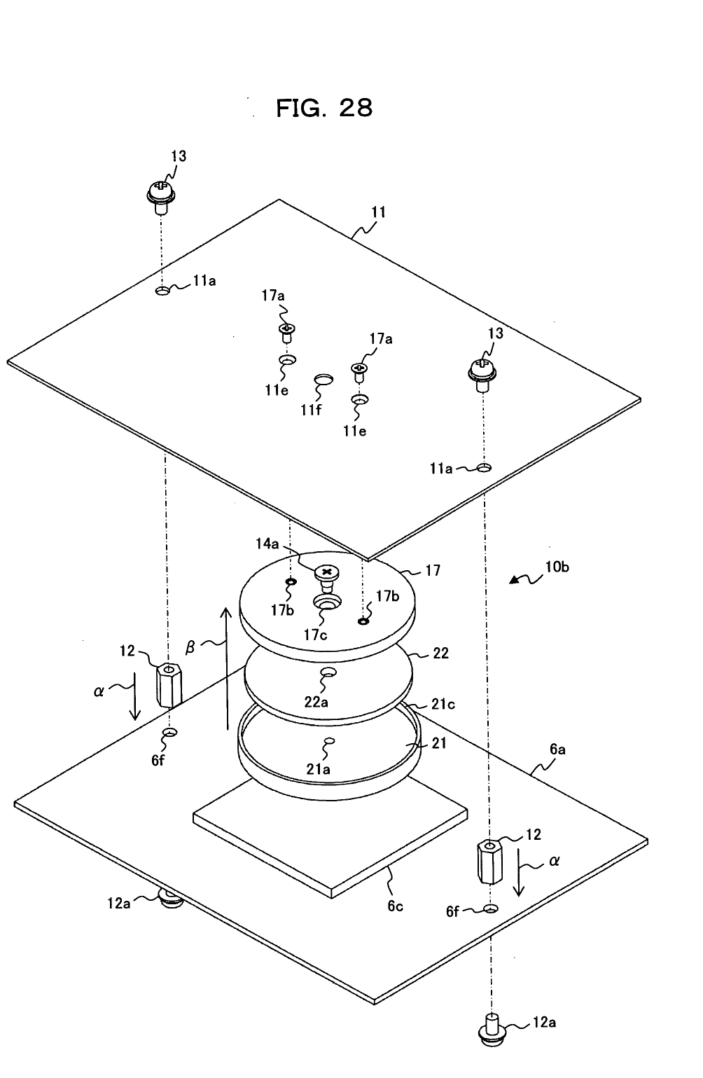

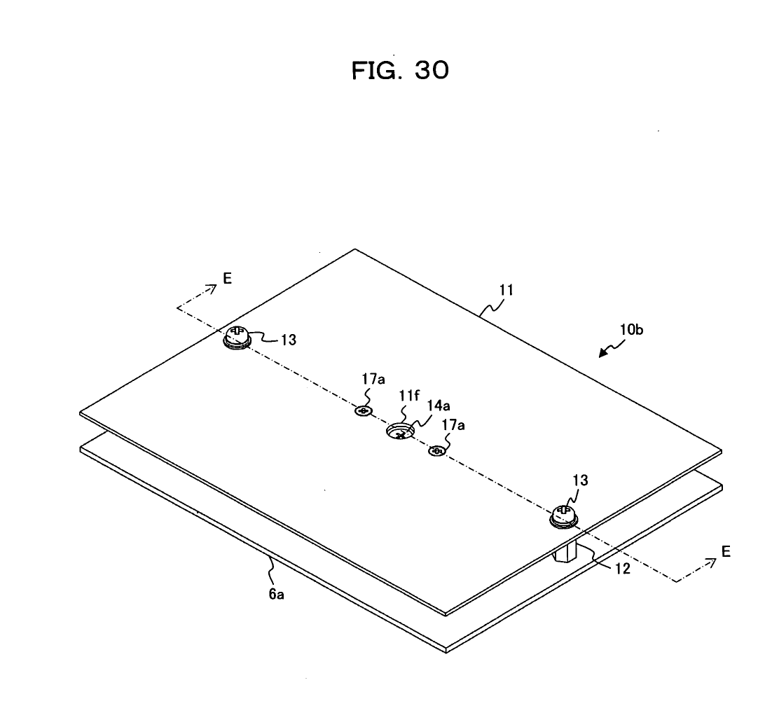

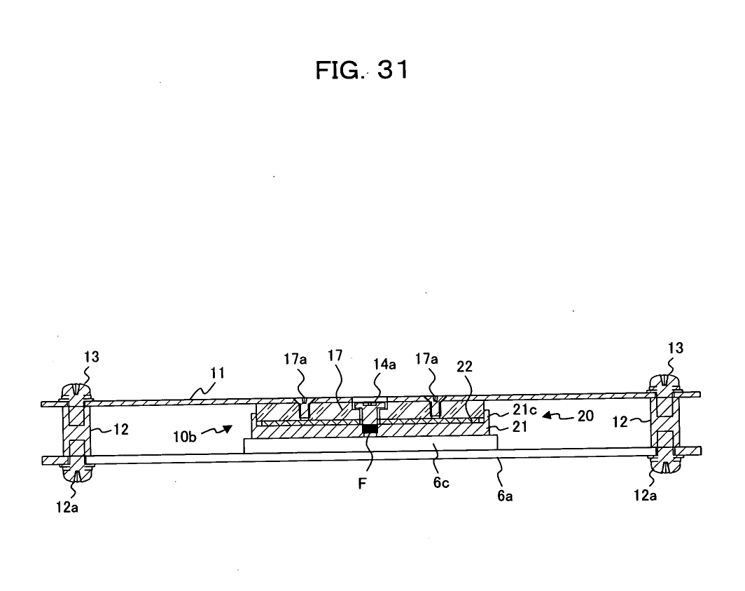

Here, referring to FIG. 28 through FIG. 31, a description will be made of an assembly sequence of the radiator device 10b (heat conductive member 21, heat conductive sheet 22, mating part 17, and radiating board 11). FIG. 31 shows an E-E cross sectional view of FIG. 30.

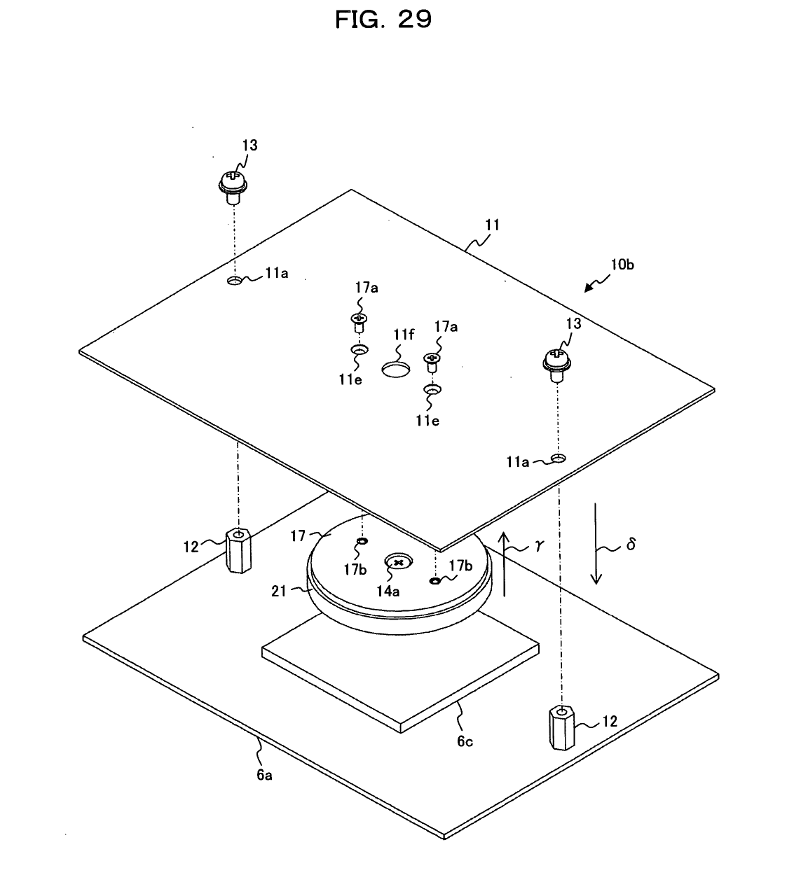

First of all, as indicated by arrow α in FIG. 28, the printed board 6a and the spacing bolts 12 are connected with the screws 12a (see FIG. 29).

Then, as indicated by arrow β, the engaging screw 14a is put into the countersunk hole 17c from the upper surface of the mating part 17, and passes through the hole 22a of the heat conductive sheet 22, and is screwed into the tapped hole 21a of the heat conductive member 21. As a result, the mating part 17 and the heat conductive member 21 are connected, sandwiching the heat conductive sheet 22 therebetween (see FIG. 29).

At that time, the end portion of the engaging screw 14a is fixed to the tapped hole 21a of the heat conductive member 21 with a locking agent (an adhesive agent) (see the solidly shaded area F in FIG. 31).

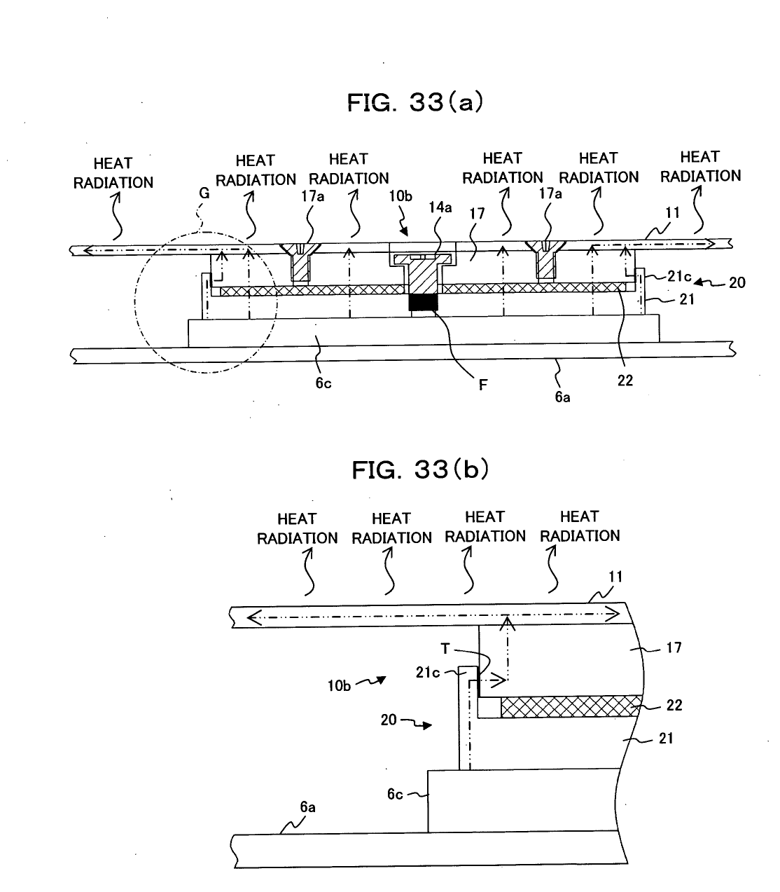

Further, in this instance, a heat conductive thermal compound (intimate contact member) T is applied to the outer peripheral surface of the mating part 17 and/or the inner peripheral surface of the wall part 21c of the heat conductive member 21, so that the outer peripheral surface of the mating part 17 makes intimate contact with the inner peripheral surface of the wall part 21c, without leaving any gap therebetween, when the mating part 17 is connected to the heat conductive member 21 (see FIG. 33(b); will be detailed later).

Then, as indicated by arrow γ in FIG. 29, the mating part 17 to which the heat conductive member 21 and the heat conductive sheet 22 (heat conductive block 20) are connected, is connected with the radiating board 11 by means of screwing the screws 17a into the tapped holes 17b of the mating part 17 (see FIG. 30).

Further, as indicated by arrow δ, the radiating board 11 is connected to the spacing bolts 12, whereby the printed board 6a is connected with the radiating board 11 to which the mating part 17 and the heat conductive block 20 are connected (see FIG. 30 and FIG. 31).

Here, as indicated by a solidly shaded part F in FIG. 31, in the radiator device 10b, the engaging screw 14a is fixed to the heat conductive member 21 with a locking agent.

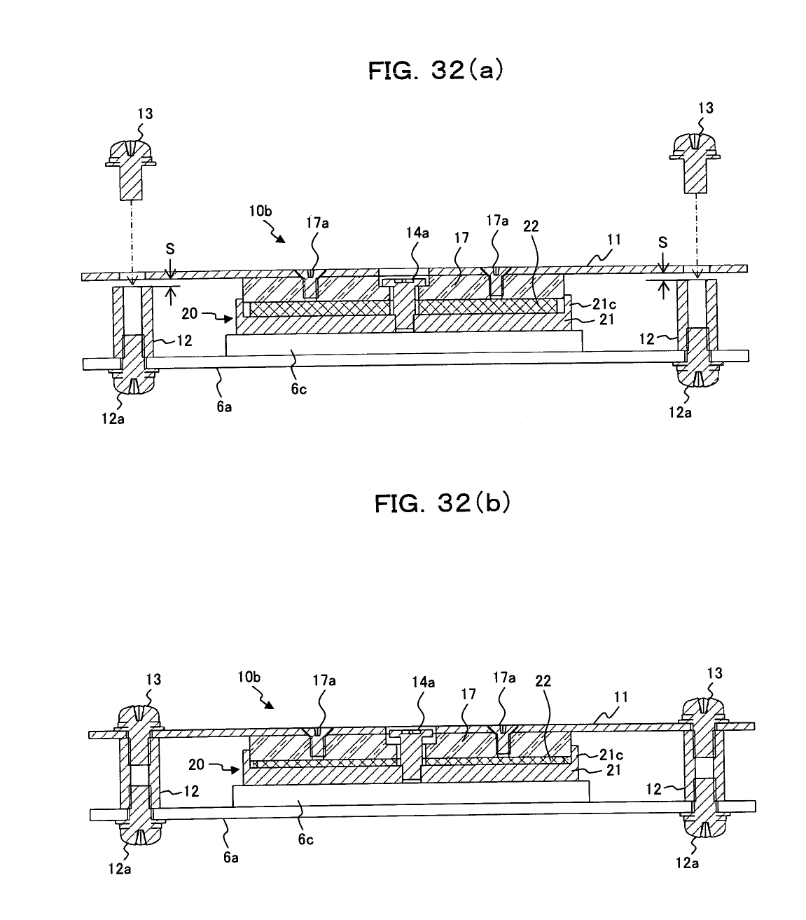

Accordingly, as shown in FIG. 32(a), if gaps S are present between the spacing bolts 12 and the radiating board 11 under a condition where the heat conductive member 21 makes intimate contact with the electronic component 6c, the heat conductive sheet 22 interposed between the heat conductive member 21 and the mating part 17 is compressed, as shown in FIG. 32(b) to remove the gap S, so that the radiating board 11 and the spacing bolts 12 are completely connected with each other. That is, by compressing the heat conductive sheet 22, it is possible to automatically adjust the position of the heat conductive member 21.

In this manner, according to the radiator device 10b of the third embodiment of the present invention, like effects and benefits to those of the first embodiment are realized.

That is, as shown in FIG. 33(a), in the radiator device 10b, as with the radiator device 10 of the first embodiment, because of the heat conductivity of the heat conductive member 21, the heat conductive sheet 22, the mating part 17, and the radiating board 11, heat generated by the electronic component 6c mounted on the printed board 6a is transferred to the heat conductive member 21, the heat conductive sheet 22, the mating part 17, and the radiating board 11, in this order, and is then radiated outside. Here, in FIG. 33(a), the two-dotted lines arrow indicates transfer of heat (heat flow) generated by the electronic component 6c.

What is more, according to the radiator device 10b, as shown in FIG. 33(b), since a heat conductive thermal compound T is applied between the outer peripheral surface of the mating part 17 and the inner peripheral surface of the wall part 21c of the heat conductive member 21, the mating part 17 makes intimate contact with the concave part, which is formed by the wall part 21c of the heat conductive member 21, without leaving any gap therebetween. As a result, as indicated by the two-dotted lines in FIG. 32(b), heat generated by the electronic component 6c is transferred from the wall part 21c to the mating part 17 via the thermal compound T, and then from the mating part 17 to the radiating board 11. In this manner, heat conductivity from the heat conductive member 21 is improved, whereby the heat radiation efficiency is improved.

Further, according to the radiator device 10b, the mating part 17 is not formed by processing the shape of the radiating board 11, but is formed independently of the radiating board 11. Thus, the shape and the size of the mating part 17 can be realized more easily than in the first embodiment, in which the shape of the radiating board 11 is processed for formation. That is, it is easy to manufacture a mating part 17 having the same or approximately the same size (here, diameter) as the inner peripheral size of the concave part formed by the wall part 21c of the heat conductive member 21.

### [4] Fourth Embodiment

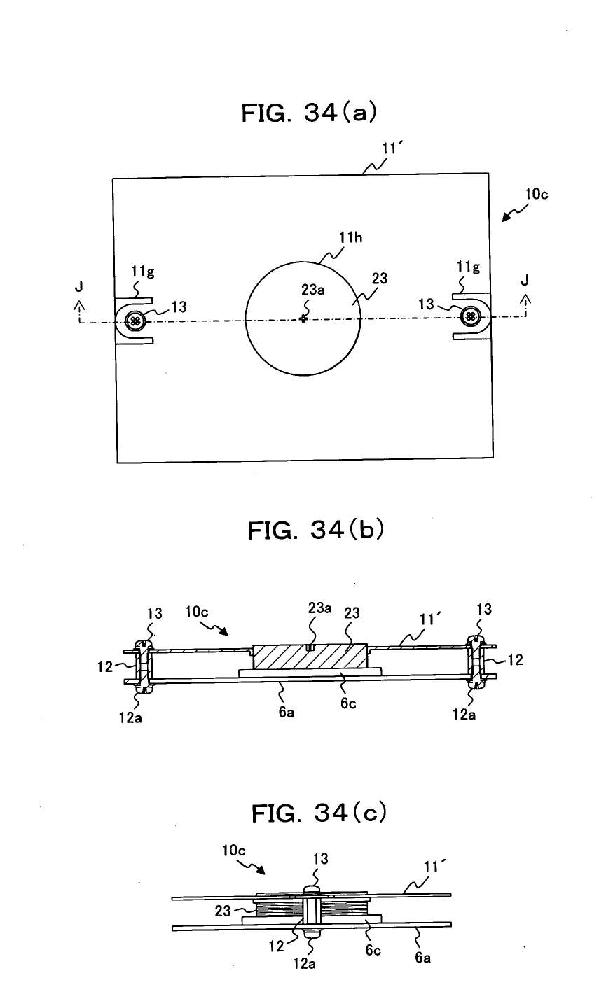

Next, referring to FIG. 34(a) through FIG. 34(c), a description will be made of a radiator device according to a fourth preferred embodiment of the present invention. Like reference numbers and characters designate similar parts or elements throughout several views of the present embodiment and the conventional art, so their detailed description is omitted here.

As shown in FIG. 34(a) through FIG. 34(c), the radiator device 10c of the fourth embodiment has a radiating board 11′ and heat conductive block 23.

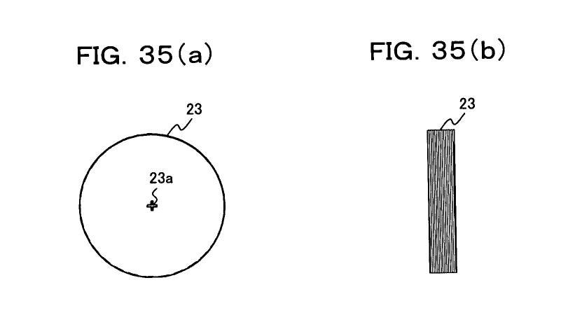

In addition, as shown in FIG. 35(a) and FIG. 35(b), the heat conductive block 23 has a cylindrical shape, and is grooved on its peripheral surface, and also has a cut 23a at the center on its upper surface. That is, in the radiator device 10c, the heat conductive block 23 itself functions as a male screw.

Here, the heat conductive block 23 is made of a heat conductive material, and it is preferably made of aluminum, copper, or stainless steel.

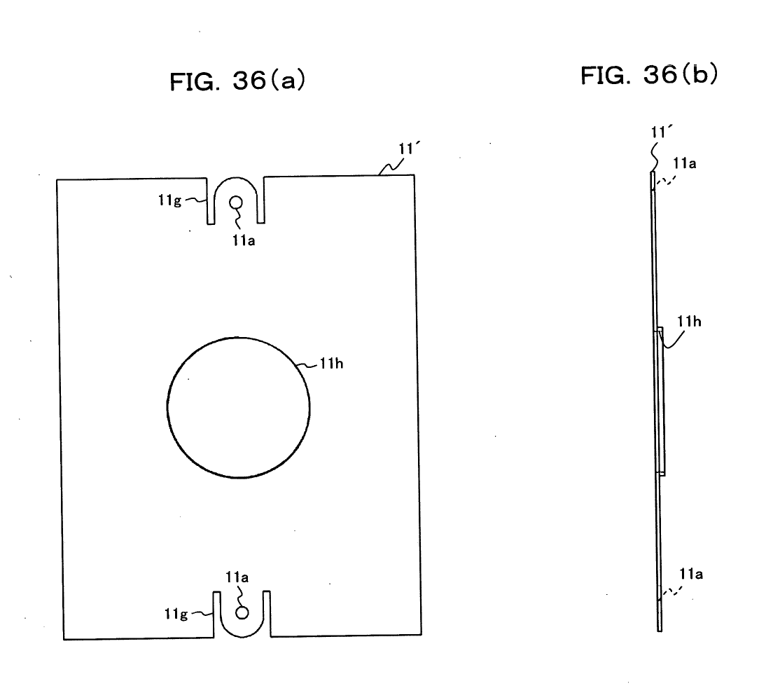

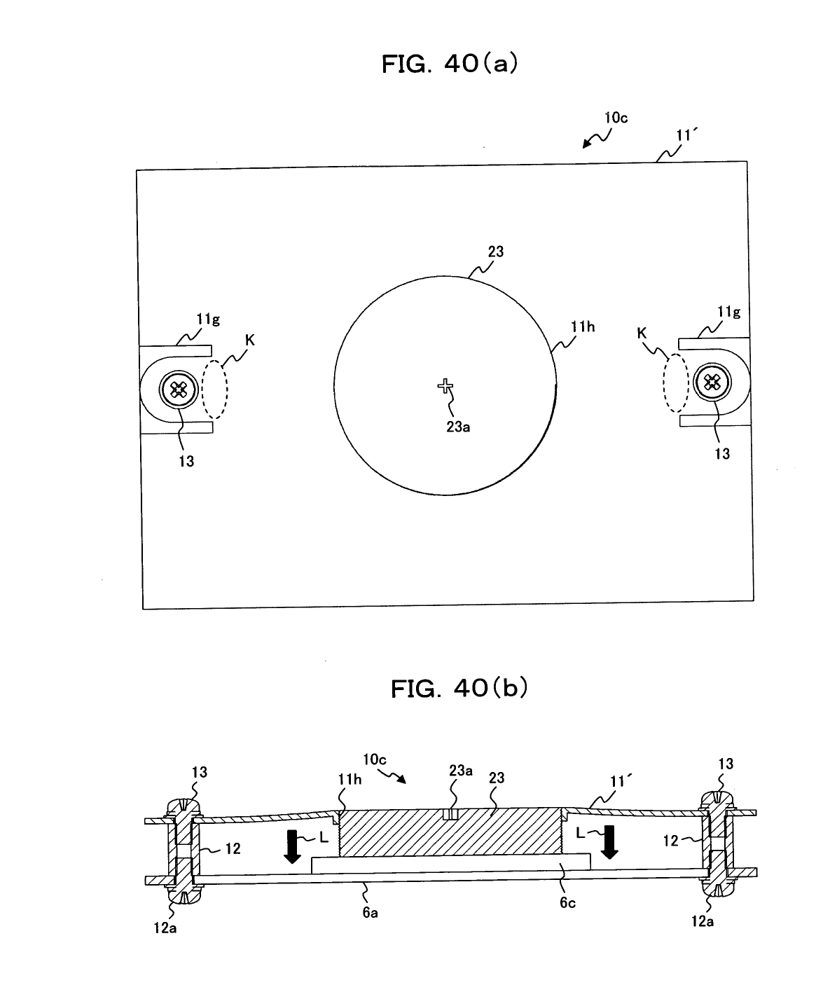

As shown in FIG. 36(a) and FIG. 36(b), there are more than one (here, two) hole 11a which is for connection with spacing bolts 12 by means of screws 13, cuts 11g, and a tapped hole 11h into which the heat conductive block 23 is screwed. Note that the cuts 11g will be detailed later with reference to FIG. 40(a) and FIG. 40(b).

As shown in FIG. 34(b) and FIG. 34(c), the heat conductive block 23 is screwed into the tapped hole 11h of the radiating board 11′, and the heat conductive block 23 is connected on a side of the radiating board 11′ that faces the printed board 6a, in such a manner that the position of the heat conductive block 23 is adjustable along a direction crossing the printed board 6a (preferably a direction perpendicular to the printed board 6a). The radiating board 11′ is connected to the printed board 6a via the spacing bolts 12 with the screws 13, whereby the heat conductive block 23 makes intimate contact with the electronic components 6c.

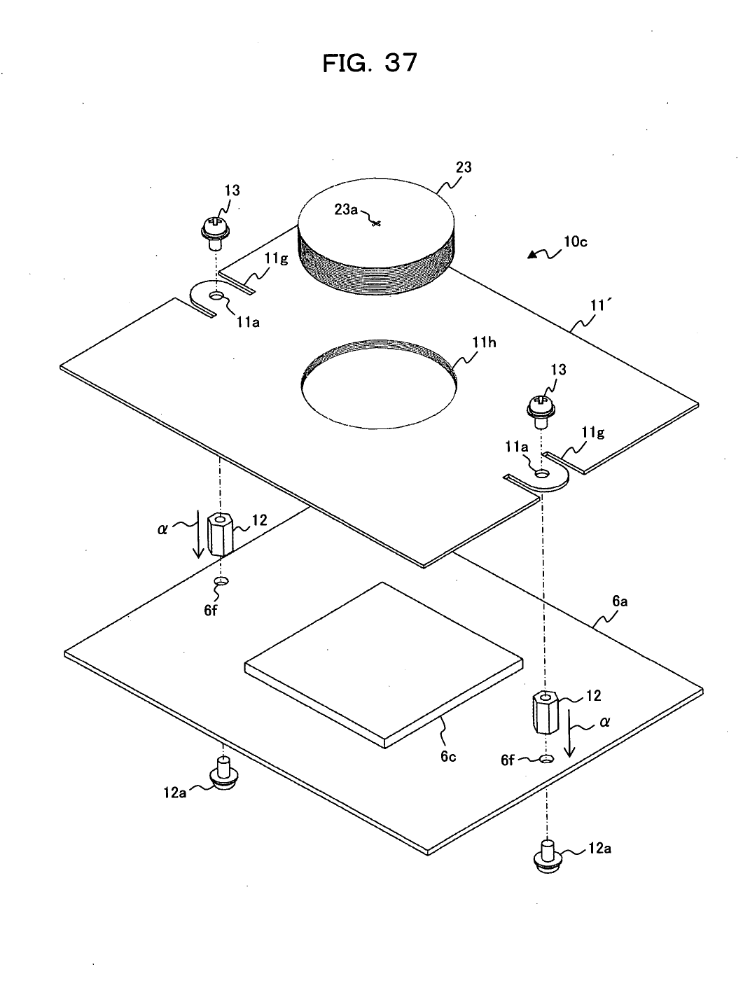

Here, referring to FIG. 37 through FIG. 39, a description will be made of an assembly sequence of the radiator device 10c (radiator 11′ and heat conductive block 23).

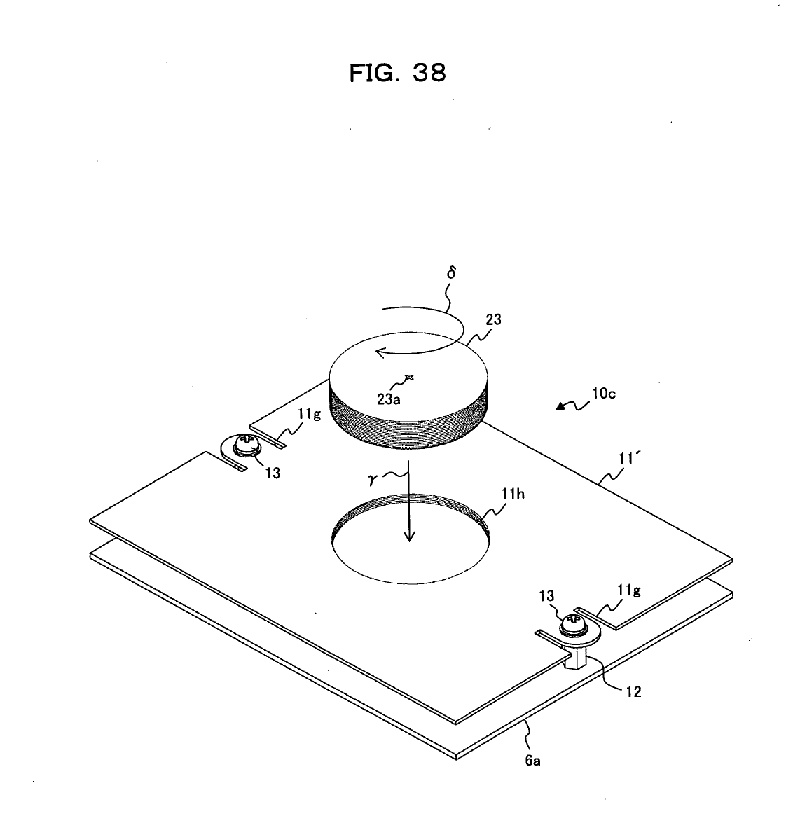

First of all, as indicated by arrow α in FIG. 37, the printed board 6a and the spacing bolts 12 are connected with the screws 12a (see FIG. 38).

Then, as indicated by arrow β, the radiating board 11′ is connected to the spacing bolts 12 by means of the screws 13 (see FIG. 38).

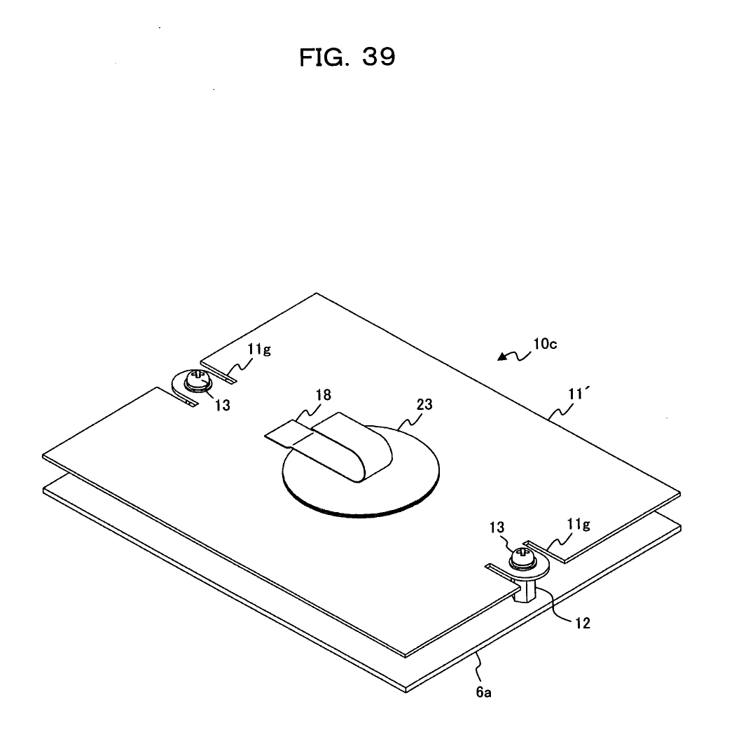

Next, as indicated by arrow γ in FIG. 38, the heat conductive block 23 is screwed into the tapped hole 11h provided on the radiating board 11′, which is connected to the printed board 6a via the spacing bolts 12, whereby the heat conductive block 23 is connected to the radiating board 11′ (see FIG. 39).

In this instance, as indicated by arrow δ, utilizing the cut 23a provided for the heat conductive block 23, a screw driver (in this example, as the cut 23a is plus-shaped, a plus-type screw driver) is used to turn the heat conductive block 23, so that the heat conductive block 23 is screwed into the tapped hole 11h of the radiating board 11′.

As shown in FIG. 39, after adjustment of the position of the heat conductive block 23 so that the heat conductive block 23 makes intimate contact with the electronic component 6c, an adhesive tape 18, for example, is put on the upper surface of the radiating board 11′ and the upper surface of the heat conductive block 23. This application of the adhesive tape 18, which extends from the upper surface of the radiating board 11′ to the upper surface of the heat conductive block 23, prevents the heat conductive block 23 from being loosened.

In this instance, as shown in FIG. 40(a), on the radiating board 11′ of the radiator device 10c, there are cuts 11g near the positions (hereinafter will be called “connection parts”) where more than one (here, two) screw 13 which connects with more than one (here, two) spacing bolt 12 connected to the printed board 6a. Thus, if the heat conductive block 23 is tightened to the tapped hole 11h over a certain degree, the radiating board 11′ is deformed to bend upward, with the connection parts as starting points, as shown in FIG. 40(b).

With the two or more (here, two) connection parts as fulcrums, a spring force is generated at positions K indicated by the broken lines in FIG. 40(a), and the spring force will generate a force (indicated by arrow L in FIG. 40(b)) of the radiating board 11′ pressing the heat conductive block 23 against the printed board 6a.

Accordingly, in the radiator device 10c, since such a spring force presses the heat conductive block 23 against the printed board 6a, all the parts of the bottom surface of the heat conductive block 23 uniformly make contact with the electronic component 6c.

That is, according to the radiator device 10c, the radiating board 11′ has more than one connection part with the printed board 6a, and there are cuts 11g, each extending toward an edge of the radiating board 11′, on the radiating board 11′ at positions near the connection parts of the radiating board 11′ so that the radiating board 11′ has a spring force which presses the heat conductive block 23 against the printed board 6a, with the connection parts as fulcrums.

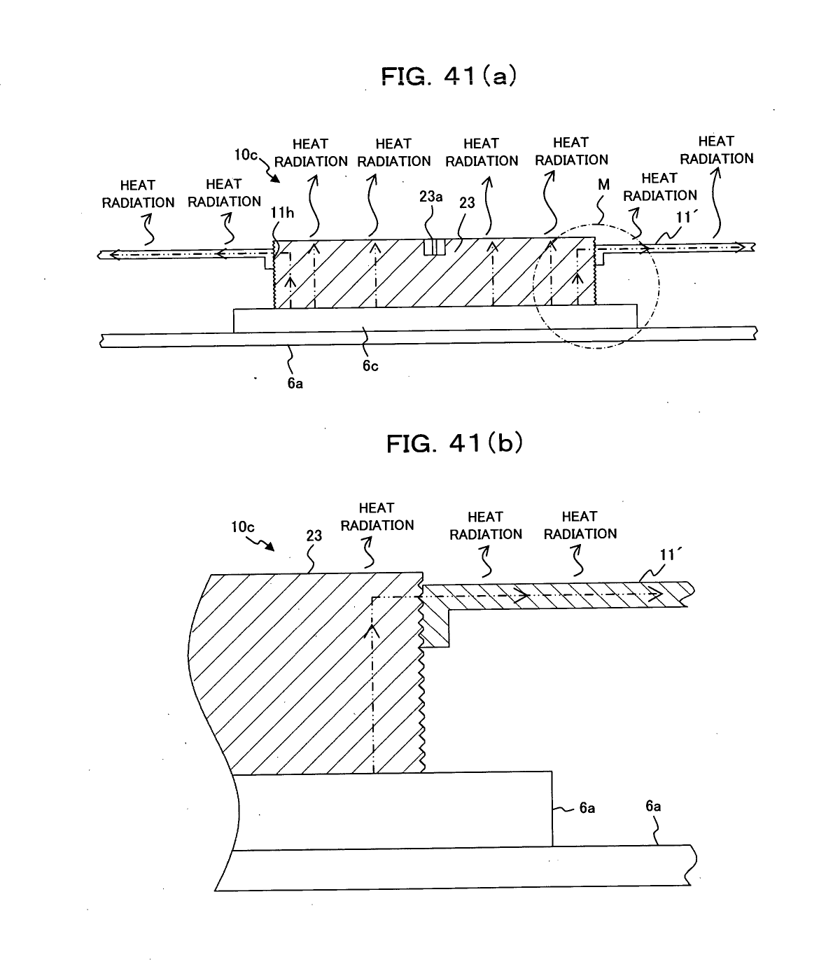

In this manner, according to the radiator device 10c of the fourth embodiment of the present invention, as shown in FIG. 41(a) and FIG. 41(b), since the heat conductive block 23 and the radiating board 11′ are heat conductive, heat generated by the electronic component 6c mounted on the printed board 6a is radiated outside directly by the heat conductive block 23. In addition, as shown in FIG. 41(b), heat transferred through the heat conductive block 23 is transferred to the radiating board 11′ at the position where the heat conductive block 23 is screwed into the radiating board 11′, that is, a contact part between the heat conductive block 23 and the tapped hole 11h. Therefore, a high heat conductivity is realized, thereby improving radiation efficiency. Here, in FIG. 41(a) and FIG. 41(b), the two-dotted lines arrow indicates transfer of heat (heat flow) generated by the electronic component 6c.

Further, since the cuts 11g are provided for the radiating board 11′, the radiating board 11′ has a spring force which presses the heat conductive block 23 against the printed board 6a. This spring force causes the heat conductive block 23 to make uniform contact with the electronic component 6c. Therefore, a high heat conductivity is realized, thereby improving radiation efficiency.

Furthermore, even if two or more electronic components 6c with different heights are mounted on the printed board 6a, the heat conductive block 23 can be tightened or loosened to easily adjust the position of the heat conductive block 23 along a direction crossing the printed board 6a. Therefore, it is possible to reliably absorb errors in height of the electronic components 6c.

### [5] Other Modifications

Further, the present invention should by no means be limited to the above-illustrated embodiments, but various changes or modifications may be suggested without departing from the gist of the invention.

For example, in the above-described embodiments, the radiating boards 11 and 11′ are connected with the printed board 6a via the spacing bolts 12, so that the radiating boards 11 and 11′ and the printed board 6a are connected, with a specific space therebetween. The present invention should not be limited to this, and spacers, instead of the spacing bolts 12, can be used to realize such a specific space between the radiating board 11 and 11′ and the printed board 6a.

Further, in the above embodiments, although the heat conductive block 20 and 23 and the mating part 15 and 17 have circular shapes, the present invention should not be limited to this.

Furthermore, in the above third embodiment of the present invention, the engaging screw 14a is fixed to the heat conductive member 21. However, as in the case of the first and the second embodiment of the present invention, the spacing bolts 12 can be adjustably attached to the heat conductive member 21, and the position of the heat conductive member 21 can be adjustable relative to the radiating board 11.

Still further, in the first and the second embodiment, also, a thermal compound T can be applied between the outer peripheral surface of the mating part 15 and the inner peripheral surface of the wall part 21c of the heat conductive member 21. This arrangement makes it possible to have the mating part 15 make intimate contact with the concave part formed by the wall part 21c of the heat conductive member 21 without leaving any gap therebetween, so that heat conductivity from the heat conductive member 21 to the mating part 15 (radiating board 11) is improved, whereby an improved heat radiation efficiency is realized.

In addition, in the above first through third embodiments, the heat conductive sheet 22 is shaped like a sheet. The present invention should not be limited to this, and as the heat conductive sheet 22, a paste-like object or a liquid-like object can be used as long as it is heat conductive and compressive.

Here, if any paste-like or liquid-like thing is used as heat conductive sheet 22, the wall part 21c of the heat conductive member 21 becomes more effective.

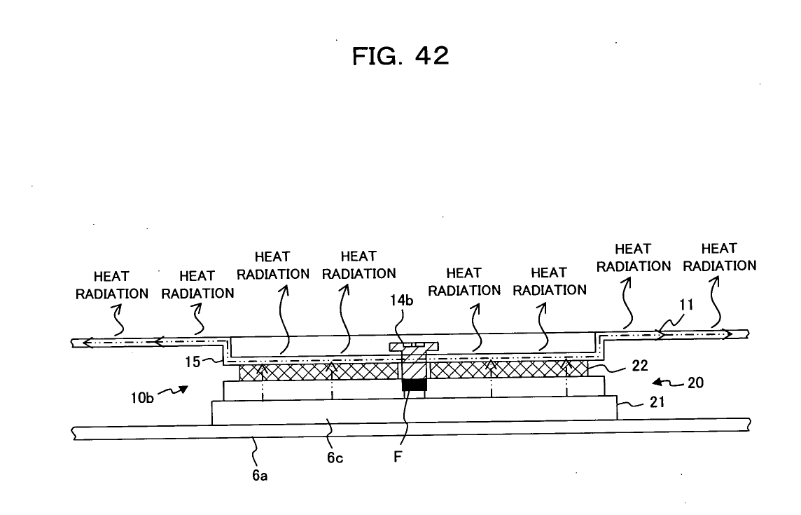

In the above first through third embodiments, the heat conductive member 21 has the wall part 21c. The present invention should not be limited to this. If a sheet-like object is used as a heat conductive sheet 22, and this heat conductive sheet 22 will not deform so as to stick out of the heat conductive member 21 when being sandwiched between the heat conductive member 21 and the radiating board 11 (mating part 15), the wall part 21c of the heat conductive member 21 can be omitted as shown in FIG. 42. Here, FIG. 42 illustrates an example of radiator device 10b of the third embodiment in which the wall part 21c of the heat conductive member 21 is omitted. In addition, in FIG. 42, as with the first embodiment, the shape of the radiating board 11 is processed in the third embodiment to form a mating part 15.

Moreover, in the above first through third embodiments, the cuts 11g can be provided for the radiating board 11 as in the fourth embodiment.

What is claimed is:

1. A radiator device, comprising:
a radiating board which is connected to an electronic component side of a printed board mounted with one or more electronic components thereon, with a specific space between said radiating board and the printed board; and a heat conductive block which is connected to a side of said radiating board that faces the printed board in such a manner that the position of said heat conductive block is adjustable along a direction crossing the printed board, said heat conductive block making intimate contact with an electronic component mounted on the printed board.

2. A radiator device as set forth in claim 1, wherein a plurality of heat conductive blocks are provided, one for each of the electronic components mounted on the printed board.

3. A radiator device as set forth in claim 1, wherein said heat conductive block is grooved on its peripheral surface, and said heat conductive block is screwed in a tapped hole provided on said radiating board.

4. A radiator device as set forth in claim 3, wherein said heat conductive block has a cut, which is for positioning adjustment, on its upper surface.

5. A radiator device as set forth in claim 1, wherein said heat conductive block includes:
a heat conductive member which makes intimate contact with the electronic component mounted on said printed board; and
a cushion member interposed between said heat conductive member and said radiating board, said cushion member being heat conductive.

6. A radiator device as set forth in claim 5, wherein said cushion member is compressible.

7. A radiator device as set forth in claim 5, wherein said cushion member has a sheet-like shape.

8. A radiator device as set forth in claim 5, wherein said heat conductive member and said radiating board are combined by means of a screw mechanism, and said cushion member is sandwiched between said heat conductive member and said radiating board.

9. A radiator device as set forth in claim 5,
wherein said heat conductive member has a wall part thereof so that said heat conductive member has a concave part thereof relative to said radiating board,
wherein said cushion member is placed in the concave part which is formed by said wall part of said heat conductive member, and
wherein said radiating board has a mating part which mates with the concave part formed by said wall part of said heat conductive member.

10. A radiator device as set forth in claim 9, wherein the mating part of said radiating board is mated with the concave part, with the mating part of said radiating board making intimate contact with an inner peripheral surface of said wall part of said heat conductive member.

11. A radiator device as set forth in claim 9, wherein a heat-conductive intimate contact member is provided between an inner peripheral surface of said wall part of said heat conductive member and an outer peripheral surface of said mating part of said radiating board so as to fill a gap therebetween.

12. A radiator device as set forth in claim 9, wherein said wall part of said heat conductive member is provided on an outside edge of said heat conductive member.

13. A radiator device as set forth in claim 5,
wherein said heat conductive block has a plurality of projections extending toward said radiating board, and
wherein a plurality of through holes are formed, for letting said projections pass therethrough, on said radiating board at positions corresponding to said plural projections of said conductive block.

14. A radiator device as set forth in claim 1,
wherein said radiating board has two or more connection parts which connects said radiating board with said printed board, and
wherein said radiating board has a cut formed thereon so that said radiating board has a spring force which presses said heat conductive block against said printed board with the two or more connection parts as fulcrums.

15. A plug-in unit, comprising:
a printed board on which one or more electronic components are mounted;
a radiating board which is connected to an electronic component side of said printed board, with a specific space between said radiating board and the printed board; and
a heat conductive block which is connected to a side of said radiating board that faces the printed board in such a manner that the position of said heat conductive block is adjustable along a direction crossing the printed board, said heat conductive block making intimate contact with an electronic component mounted on the printed board.

16. A plug-in unit as set forth in claim 15, wherein a plurality of heat conductive blocks are provided, one for each of the electronic components mounted on said printed board.

17. A plug-in unit as set forth in claim 15, wherein said heat conductive block is grooved on its peripheral surface, and said heat conductive block is screwed in a tapped hole provided on said radiating board.

18. A plug-in unit as set forth in claim 15, wherein said heat conductive block includes:
a heat conductive member which makes intimate contact with the electronic component mounted on said printed board; and
a cushion member interposed between said heat conductive member and said radiating board, said cushion member being heat conductive.

19. A plug-in unit as set forth in claim 18, wherein said heat conductive member and said radiating board are combined by means of a screw mechanism, and said cushion member is sandwiched between said heat conductive member and said radiating board.

20. A plug-in unit as set forth in claim 18,
wherein said heat conductive member has a wall part thereof so that said heat conductive member has a concave part thereof relative to said radiating board,
wherein said cushion member is placed in the concave part which is formed by said wall part of said heat conductive member, and
wherein said radiating board has a mating part which mates with the concave part formed by said wall part of said heat conductive member.
